(19) United States
(12) Patent Application Publication
(10) Pub. No.: US 2025/0295006 A1
(43) Pub. Date: Sep. 18, 2025

(54) DISPLAY DEVICE

(71) Applicant: Samsung Display Co., Ltd., Yongin-Si (KR)

(72) Inventors: Hang Jae LEE, Yongin-si (KR); Min Jung NA, Yongin-si (KR); Ki Ho BANG, Yongin-si (KR); In Hyuck YEO, Yongin-si (KR); Won Suk CHOI, Yongin-si (KR)

(21) Appl. No.: 18/948,467

(22) Filed: Nov. 15, 2024

(30) Foreign Application Priority Data
Mar. 15, 2024 (KR) 10-2024-0036358

(51) Int. Cl. H10K 59/80; H10K 59/124

(52) U.S. Cl. CPC H10K 59/873; H10K 59/124

(57) ABSTRACT

A display device comprises a display panel emitting light for image display. The display panel comprises a substrate, a circuit layer disposed on the substrate, and an element layer disposed on the circuit layer. A main region of the substrate comprises a display area, and a non-display area disposed around the display area. The display area comprises a front display area and a peripheral display area disposed around the front display area and having a curved shape. The display panel further comprises a strain adjustment part which overlaps corner areas of the peripheral display area adjacent to corners of an edge of the substrate and is spaced apart from the edge of the substrate. The substrate has a first thickness in a portion not overlapping the strain adjustment part. A portion of the substrate overlapping the strain adjustment part has a second thickness smaller than the first thickness.

### CROSS-REFERENCE TO RELATED APPLICATION

This application claims priority from Korean Patent Application No. 10-2024-0036358 filed on Mar. 15, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device.

### 2. Description Of The Related Art

With the advance of information-oriented society, more and more demands are placed on display devices for displaying images in various ways. For example, display devices are employed in various electronic devices such as smartphones, digital cameras, laptop computers, navigation devices, and smart televisions.

The display device may be a flat panel display device such as a liquid crystal display device, a field emission display device and a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have relatively superior performance in power consumption, response speed, luminous efficiency, luminance, and wide viewing angle compared to other display devices.

In the display device, a display surface from which light is emitted may include a display area in which an image is displayed, and a non-display area around the display area. Emission areas emitting light with respective luminances and colors may be arranged in the display area.

### SUMMARY

When the display area is disposed wider in the display surface of the display device, an area of the display device from which light is emitted is widened, and thus aesthetics may be improved and compatibility with various electronic devices may be improved. Therefore, measures to reduce the width of the non-display area in the display surface have been researched and developed.

However, since there are wires and elements that are disposed in the non-display area, there is a limit to the reduction of the width of the non-display area.

In view of the above, aspects of the present disclosure provide a display device in which the width of a non-display area visually recognized in a front direction facing a display surface may be reduced by transforming the edge of the display area into a curved shape.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device comprises a display panel emitting light for image display. The display panel comprises a substrate, a circuit layer disposed on the substrate, and an element layer disposed on the circuit layer. A main region of the substrate comprises a display area in which emission areas are arranged, and a non-display area disposed around the display area. The display area comprises a front display area and a peripheral display area disposed around the front display area and having a curved shape. The display panel further comprises a strain adjustment part which overlaps corner areas of the peripheral display area adjacent to corners of an edge of the substrate and is spaced apart from the edge of the substrate. The substrate has a first thickness in a portion not overlapping the strain adjustment part. A portion of the substrate overlapping the strain adjustment part has a second thickness smaller than the first thickness due to the strain adjustment part.

The substrate comprises a first support layer; a barrier layer disposed on the first support layer; and a second support layer disposed with a third thickness in a portion not overlapping the strain adjustment part on the barrier layer. The strain adjustment part comprises a first groove penetrating at least a part of the first support layer; and a second groove overlapping the first groove and penetrating a part of the second support layer.

An inclination of a side surface of the second groove is greater than or equal to 5° and less than or equal to 15° relative to a plane of the substrate.

A thickness of a portion of the second support layer overlapping a bottom surface of the second groove is 50% or more of the third thickness and 85% or less of the third thickness.

The thickness of the portion of the second support layer overlapping the bottom surface of the second groove is 3 μm or more.

The first support layer has a fourth thickness in a portion not overlapping the strain adjustment part greater than the third thickness. A thickness of a portion of the first support layer overlapping the first groove is 10% or less of the fourth thickness.

A minimum value of a separation distance between the strain adjustment part and the edge of the substrate is 150 μm to 180 μm.

The peripheral display area comprises the corner areas, and side areas parallel to edge sides of the substrate. The strain adjustment part further overlaps some portions of the side areas adjacent to the corner areas.

The strain adjustment part further overlaps some portions of the non-display area adjacent to the corner areas.

The strain adjustment part further overlaps the side areas.

The strain adjustment part further overlaps some portions of the front display area adjacent to the corner areas.

The strain adjustment part further overlaps a portion of the non-display area adjacent to the peripheral display area.

The strain adjustment part further overlaps some portions of the front display area adjacent to the corner areas.

The front display area comprises a first side and a second side extending in a first direction and opposite to each other, and a third side and a fourth side extending in a second direction intersecting the first direction and opposite to each other. The peripheral display area comprises a first side area, a second side area, a third side area, and a fourth side area in contact with the first side, the second side, the third side, and the fourth side of the front display area, respectively; a first corner area in contact with a vertex where the first side and the third side meet and disposed between the first side area and the third side area; a second corner area in contact with a vertex where the second side and the third side meet and disposed between the second side area and the third side area; a third corner area in contact with a vertex where the second side and the fourth side meet and disposed between the second side area and the fourth side area; and a fourth corner area is in contact with a vertex where the first side and the fourth side meet and disposed between the first side area and the fourth side area. The strain adjustment part overlaps the first corner area, the second corner area, the third corner area, and the fourth corner area.

The display device further comprises a bracket supporting the display panel; and a cover window disposed on the display panel and coupled to the bracket. The peripheral display area is curved toward the bracket.

According to an aspect of the present disclosure, there is provided a display device comprises a display panel emitting light for image display; a bracket supporting the display panel; and a cover window disposed on the display panel and coupled to the bracket. The display panel comprises a substrate, a circuit layer disposed on the substrate, and an element layer disposed on the circuit layer. A main region of the substrate comprises a display area in which emission areas are arranged, and a non-display area disposed around the display area. The display area comprises a front display area and a peripheral display area disposed around the front display area and having a curved shape toward the bracket. The display panel further comprises a strain adjustment part which overlaps corner areas of the peripheral display area adjacent to corners of an edge of the substrate and is spaced apart from the edge of the substrate. The substrate has a first thickness in a portion not overlapping the strain adjustment part. A portion of the substrate overlapping the strain adjustment part has a second thickness smaller than the first thickness due to the strain adjustment part. The substrate comprises a first support layer; a barrier layer disposed on the first support layer; and a second support layer disposed on the barrier layer. The strain adjustment part comprises a first groove penetrating at least a part of the first support layer; and a second groove overlapping the first groove and penetrating a part of the second support layer.

The second support layer is disposed with a third thickness in a portion not overlapping the strain adjustment part. The first support layer is disposed with a fourth thickness in a portion not overlapping the strain adjustment part greater than the third thickness. A thickness of a portion of the second support layer overlapping a bottom surface of the second groove is 50% or more of the third thickness and 85% or less of the third thickness. A thickness of a portion of the first support layer overlapping the first groove is 10% or less of the fourth thickness.

A minimum value of a separation distance between the strain adjustment part and the edge of the substrate is 150 μm to 180 μm.

The peripheral display area comprises the corner areas, and side areas parallel to edge sides of the substrate. The strain adjustment part further overlaps at least some portions of the side areas adjacent to the corner areas.

The strain adjustment part further overlaps at least some portions of the non-display area adjacent to the corner areas.

The display device according to embodiments may include a display panel that emits light for image display, and a main region of a substrate of the display panel may include a display area in which emission areas are arranged, and a non-display area disposed around the display area. The display area may include a front display area, and a peripheral display area disposed around the front display area and having a curved shape. As such, as the display area includes the peripheral display area in a curved shape,

the non-display area connected to the peripheral display area may have a curved shape together with the peripheral display area. That is, the width of the curved non-display area that is visually recognized in the front direction facing the display surface may be smaller than the width of the non-display area in an unfolded state. Therefore, in the display surface of the display device, the width of the display area that is visually recognized in the front direction may increase, thereby improving the aesthetics and compatibility of the display device.

Each of corner areas of the curved peripheral display area may be a double curvature region where the curvatures of one side and the other side are different from each other. Since such a double curvature region is bent at two curvatures, it may have higher bending stress than a region bent at one curvature. As a result, defects such as delamination and breakage of the substrate may occur more readily in the double curvature region.

In order to prevent this, according to embodiments, the display panel further includes a strain adjustment part that overlaps the corner areas of the peripheral display area adjacent to the corners of the edge of the substrate and is spaced apart from the edge of the substrate.

The substrate is provided with a first thickness, but a portion of the substrate that overlaps the strain adjustment part has a second thickness that is smaller than the first thickness due to the strain adjustment part.

That is, by means of the strain adjustment part, the corner areas of the substrate, which are double curvature regions, may have a higher strain by being disposed at a second thickness which is relatively thin. Therefore, defects caused by high bending stress in the double curvature region may be reduced.

Hence, the lifespan and quality reliability of the display device may be improved.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings.

FIG. 1 is a perspective view illustrating a display device according to embodiments.

FIG. 2 is a cross-sectional view taken along line A-A′ of FIG. 1.

FIG. 3 is a cross-sectional view showing the display panel taken along line B-B′ of FIG. 1.

FIG. 4 is a plan view showing the substrate of FIG. 3.

FIG. 5 is a layout diagram illustrating part C of FIG. 4.

FIG. 6 is an equivalent circuit diagram showing the light emitting pixel driver of FIG. 5 according to an embodiment.

FIG. 7 is a cross-sectional view illustrating a light emitting element, a first transistor, and a sixth transistor of the light emitting pixel driver according to an embodiment of FIG. 6.

FIG. 8 is an equivalent circuit diagram showing the light emitting pixel driver of FIG. 5 according to an embodiment.

FIG. 9 is a cross-sectional view showing a light emitting element, a first transistor, a second transistor, a fourth transistor, and a sixth transistor of the light emitting pixel driver according to an embodiment of FIG. 8.

FIG. 10 is a plan view illustrating a display panel according to embodiments.

FIG. 11 is a cross-sectional view taken along line D-D′ of FIG. 10 according to an embodiment.

FIG. 12 is a cross-sectional view taken along line E-E′ of FIG. 10 according to an embodiment. 15

FIGS. 13, 14, 15, 16, and 17 are process diagrams illustrating steps of a process of disposing a strain adjustment part according to embodiments.

FIG. 18 is a cross-sectional view taken along line D-D′ of FIG. 10 according to an embodiment.

20 FIG. 19 is a plan view illustrating a display panel according to an embodiment.

FIG. 20 is a cross-sectional view taken along line F-F′ of FIG. 19.

FIGS. 21, 22, 23, and 24 are plan views showing a display panel according to embodiments.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

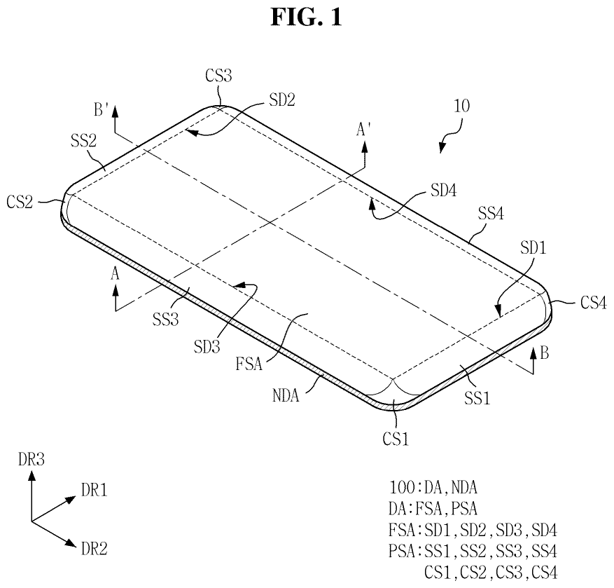

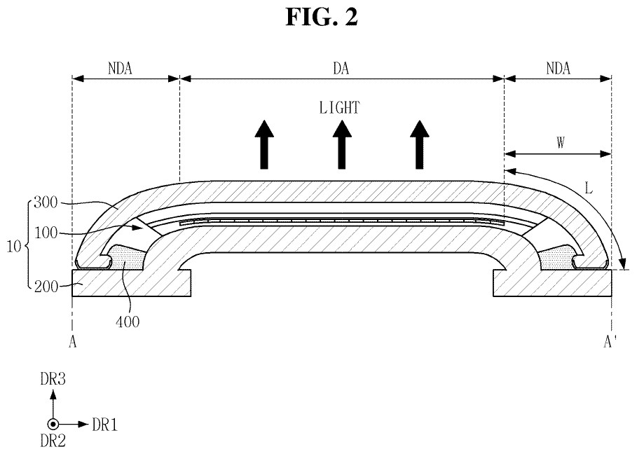

FIG. 1 is a perspective view illustrating a display device 10 according to embodiments. FIG. 2 is a cross-sectional view taken along line A-A′ of FIG. 1.

Referring to FIG. 1, the display device 10 according to embodiments, which is a device for displaying a moving image or a still image, may be used as a display screen of various devices, such as a television, a laptop computer, a monitor, a billboard and an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and an ultra-mobile PC (UMPC).

In an embodiment, the display device 10 according to embodiments may be applied to a dashboard of a vehicle, a center fascia of a vehicle, a center information display (CID) disposed on a dashboard of a vehicle, a room mirror display in place of side mirrors of a vehicle, or a display disposed on a rear surface of a front seat for rear seat entertainment of a vehicle.

Referring to FIG. 2, the display device 10 according to embodiments may include a display panel 100 that emits light for image display.

The display device 10 according to embodiments may further include a bracket 200 supporting the display panel 100, and a cover window 300 disposed on the display panel 100 and coupled to the bracket 200.

The display panel 100 may be a light emitting display panel including a light emitting element. For example, the display panel 100 may be an organic light emitting display panel using an organic light emitting diode including an organic light emitting layer, a micro light emitting diode display panel using a micro LED, a quantum dot light emitting display panel using a quantum dot light emitting diode including a quantum dot light emitting layer, or an inorganic light emitting display panel using an inorganic light emitting element including an inorganic semiconductor. The following description is directed to the case where the display panel 100 is an organic light emitting display panel.

The bracket 200 may include a rigid insulating material to prevent deformation of the display panel 100 and to mitigate external physical and electrical impacts on the display panel 100. However, this is merely an example, and the material of the bracket 200 may be variously changed.

The cover window 300 may include a light transmitting material. The cover window 300 may be made of an inorganic material such as glass, or an organic material such as plastic or a polymer material.

The cover window 300 may be secured to the bracket 200 through an adhesive material 400 disposed on the edge.

The cover window 300 may be attached to the display panel 100 by a transparent adhesive member, such as an optically clear adhesive (OCA) film or an optically clear resin (OCR).

By means of such a cover window 300, the display panel 100 may be protected from electrical and physical impacts on the display surface.

As shown in FIG. 1, according to embodiments, the display panel 100 may include a display area DA from which light is emitted, and a non-display area NDA disposed around the display area DA.

The display area DA may include a front display area FSA having a flat shape and a peripheral display area PSA disposed around the front display area FSA and having a curved shape.

The front display area FSA may include a first side SD1 and a second side SD2 that extend in a first direction DR1 and are opposite to each other, and a third side SD3 and a fourth side SD4 that extend in a second direction DR2, make connection between the first side SD1 and the second side SD2, and are opposite to each other.

For example, the first side SD1 and the second side SD2 may have a shorter length than the third side SD3 and the fourth side SD4. That is, the front display area FSA may have a quadrilateral shape in plan view.

In another example, corners where each of the first and second sides SD1 and SD2 and each of the third and fourth sides SD3 and SD4 meet may have an arc shape or a right-angled vertex shape.

However, the shape of the front display area FSA according to embodiments is not limited to the quadrangle shown in FIG. 1 and may be a circle, an ellipse, or a polygon other than the quadrangle.

The peripheral display area PSA may include a first side area SS1 in contact with the first side SD1 of the front display area FSA, a second side area SS2 in contact with the second side SD2 of the front display area FSA, a third side area SS3 in contact with the third side SD3 of the front display area FSA, and a fourth side area SS4 in contact with the fourth side SD4 of the front display area FSA.

In addition, the peripheral display area PSA may further include a first corner area CS1 that is in contact with a vertex where the first side SD1 and the third side SD3 meet and is disposed between the first side area SS1 and the third side area SS3, a second corner area CS2 that is in contact with a vertex where the second side SD2 and the third side SD3 meet and is disposed between the second side area SS2 and the third side area SS3, a third corner area CS3 that is in contact with a vertex where the second side SD2 and the fourth side SD4 meet and is disposed between the second side area SS2 and the fourth side area SS4, and a fourth corner area CS4 that is in contact with a vertex where the first side SD1 and the fourth side SD4 meet and is disposed between the first side area SS1 and the fourth side area SS4.

The first side area SS1 may extend from the first side SD1 and be curved toward the bracket 200 with a predetermined first curvature.

The second side area SS2 may extend from the second side SD2 and be curved toward the bracket 200 with a second curvature. The second curvature may be in the same range as the first curvature.

The third side area SS3 may extend from the third side SD3 and be curved toward the bracket 200 with a predetermined third curvature. The third curvature may be in the same or similar range as the first curvature or the second curvature, but is not limited thereto.

The fourth side area SS4 may extend from the fourth side SD4 and be curved toward the bracket 200 with a fourth curvature. The fourth curvature may be in the same range as the third curvature.

The first corner area CS1 may be disposed between one side of the first side area SS1 and one side of the third side area SS3.

The first corner area CS1 may be a double curvature region bent by the first curvature of the first side area SS1 in contact with one side thereof and the third curvature of the third side area SS3 in contact with the other side thereof.

The second corner area CS2 may be disposed between one side of the second side area SS2 and the other side of the third side area SS3.

The second corner area CS2 may be a double curvature region bent by the second curvature of the second side area SS2 in contact with one side thereof and the third curvature of the third side area SS3 in contact with the other side thereof.

The third corner area CS3 may be disposed between the other side of the second side area SS2 and one side of the fourth side area SS4.

The third corner area CS3 may be a double curvature region bent by the second curvature of the second side area SS2 in contact with one side thereof and the fourth curvature of the fourth side area SS4 in contact with the other side thereof.

The fourth corner area CS4 may be disposed between the other side of the first side area SS1 and the other side of the fourth side area SS4.

The fourth corner area CS4 may be a double curvature region bent by the first curvature of the first side area SS1 in contact with one side thereof and the fourth curvature of the fourth side area SS4 in contact with the other side thereof.

That is, since the first corner area CS1, the second corner area CS2, the third corner area CS3, and the fourth corner area CS4 are each a double curvature region affected by two different curvatures, they may be subjected to a higher bending stress compared to the first side area SS1, the second side area SS2, the third side area SS3, and the fourth side area SS4.

As described above, according to embodiments, the display area DA includes not only the front display area FSA in a flat shape, but also the peripheral display area PSA in a shape curved toward the bracket 200.

Since the non-display area NDA is disposed around the display area DA, it may be connected to the outer edge of the peripheral display area PSA.

The bending shape of the peripheral display area PSA may extend to the non-display area NDA. That is, the non-display area NDA may have a curved shape together with the curved peripheral display area PSA.

In an embodiment, the bending shape of the peripheral display area PSA may not extend to the non-display area NDA, and the non-display area NDA may be disposed in a flat shape in a direction perpendicular to the front display area FSA.

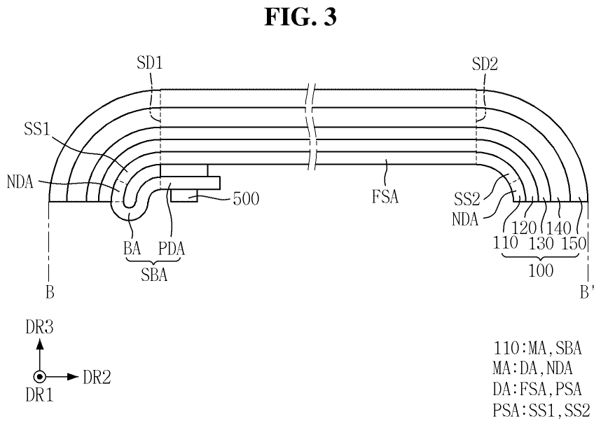

Additionally, a portion of the non-display area NDA adjacent to the peripheral display area PSA may have a curved shape together with the peripheral display area PSA, while the other remaining portion adjacent to the edge of a substrate 110 (see FIG. 3) may have a flat shape in a direction perpendicular to the front display area FSA.

As shown in FIG. 2, the display device 10 may include the display area DA from which light of the display panel 100 is emitted, and the non-display area NDA which is disposed around the display area DA and from which no light is emitted.

The peripheral display area PSA (see FIG. 1) at the edge of the display area DA of the display panel 100 may be curved toward the bracket 200. Accordingly, the non-display area NDA of the display device 10 may be disposed on the side surface of the display device 10 due to the curved shape of the peripheral display area PSA.

In addition, each of the bracket 200 and the cover window 300 may have a curved edge, similarly to the display panel 100.

Accordingly, in the display device 10, a width W of the non-display area NDA in a curved shape visually recognized in a front direction (e.g., a direction opposite to a third direction DR3) facing light of the front display area FSA (see FIG. 1) of the display device 10 may be smaller than a width L of the non-display area NDA in an unfolded state.

Therefore, as the width W of the non-display area NDA visually recognized in the front direction in the display surface of the display device 10 is reduced, the proportion of the display area DA of the display surface may be increased, thereby improving the aesthetics and compatibility of the display device 10.

FIG. 3 is a cross-sectional view showing the display panel 100 taken along line B-B′ of FIG. 1.

Referring to FIG. 3, the display panel 100 of the display device 10 according to embodiments may include the substrate 110, a circuit layer 120 disposed on the substrate 110, and an element layer 130 disposed on the circuit layer 120.

The substrate 110 may include a main region MA and a sub-region SBA.

The main region MA may include the display area DA and the non-display area NDA disposed around the display area DA.

The display area DA may include the front display area FSA, and the peripheral display area PSA disposed around the front display area FSA and having a curved shape.

The edge of the front display area FSA may include the first side SD1 and the second side SD2 opposite to each other in the second direction DR2.

The peripheral display area PSA may include the first side area SS1 disposed between the first side SD1 of the front display area FSA and the non-display area NDA, and the second side area SS2 disposed between the second side SD2 of the front display area FSA and the non-display area NDA.

In addition, as shown in FIG. 1, the edge of the front display area FSA may further include the third side SD3 and the fourth side SD4 opposing each other in the first direction DR1.

The peripheral display area PSA may include the third side area SS3 disposed between the third side SD3 of the front display area FSA and the non-display area NDA, and the fourth side area SS4 disposed between the fourth side SD4 of the front display area FSA and the non-display area NDA.

In addition, the peripheral display area PSA may further include the first corner area CS1 that is in contact with a vertex where the first side SD1 and the third side SD3 meet and is disposed between the first side area SS1 and the third side area SS3, the second corner area CS2 that is in contact with a vertex where the second side SD2 and the third side SD3 meet and is disposed between the second side area SS2 and the third side area SS3, the third corner area CS3 that is in contact with a vertex where the second side SD2 and the fourth side SD4 meet and is disposed between the second side area SS2 and the fourth side area SS4, and the fourth corner area CS4 that is in contact with a vertex where the first side SD1 and the fourth side SD4 meet and is disposed between the first side area SS1 and the fourth side area SS4.

As shown in FIG. 3, according to embodiments, the display device 10 may further include a display driving circuit 500, provided as an integrated circuit (IC) chip and mounted on a pad area PDA of the sub-region SBA of the substrate 110.

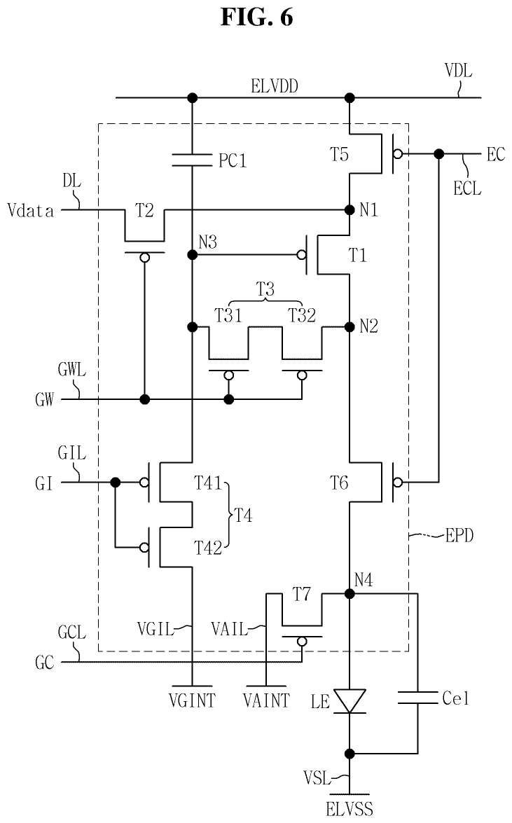

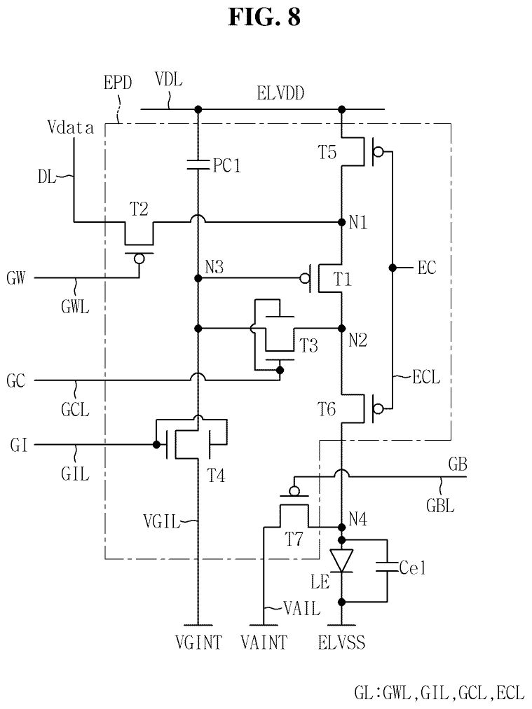

The display driving circuit 500 may supply a data signal Vdata (see FIGS. 6 and 8) to data lines DL (see FIGS. 6 and 8) of the circuit layer 120.

According to embodiments, the display device 10 may further include a circuit board bonded to the pad area PDA of the sub-region SBA of the substrate 110. The circuit board may be bonded to pads disposed in the sub-region SBA of the substrate 110 by using a low-resistance, high-reliability material such as an anisotropic conductive film or SAP.

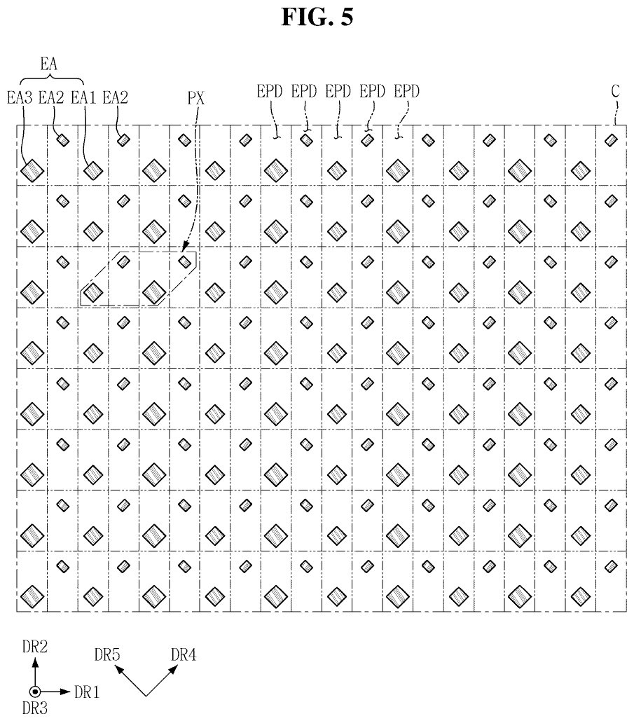

Emission areas EA (see FIG. 5) may be arranged in the display area DA.

The circuit layer 120 may include light emitting pixel drivers EPD (see FIG. 5) arranged side by side in the first direction DR1 and the second direction DR2.

The element layer 130 may include light emitting elements LE (see FIGS. 6, 7, 8, and 9) respectively disposed in the emission areas EA. The light emitting elements LE (see FIGS. 6, 7, 8, and 9) may be respectively electrically connected to the light emitting pixel drivers EPD (see FIG. 5).

The display panel 100 according to embodiments may further include an encapsulation layer 140 disposed on the element layer 130, and a touch sensor layer 150 disposed on the encapsulation layer 140.

The encapsulation layer 140 is disposed on the element layer 130 and may have a structure in which two or more inorganic films and at least one organic film are alternately stacked. The touch sensor layer 150 may include touch electrodes for detecting a signal that

varies depending on the touch of a person or an object and sensing a point in the main region MA in which the touch of the person or the object has occurred.

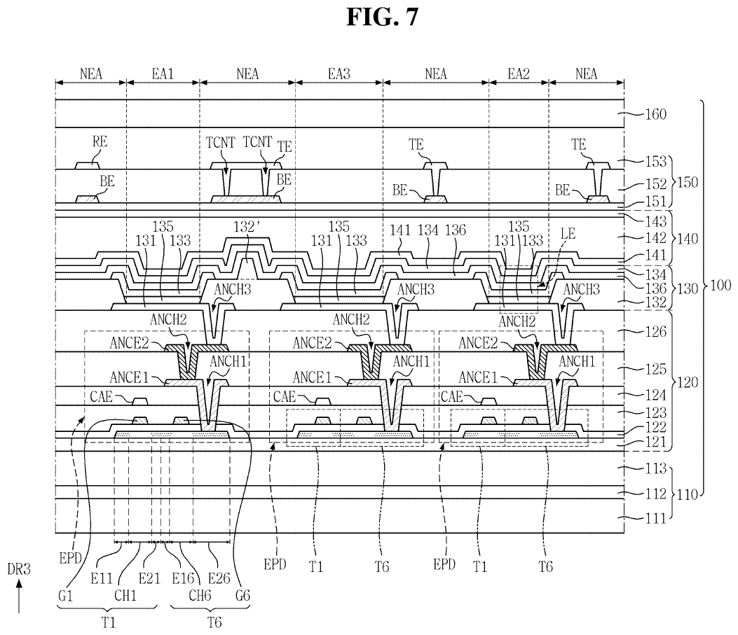

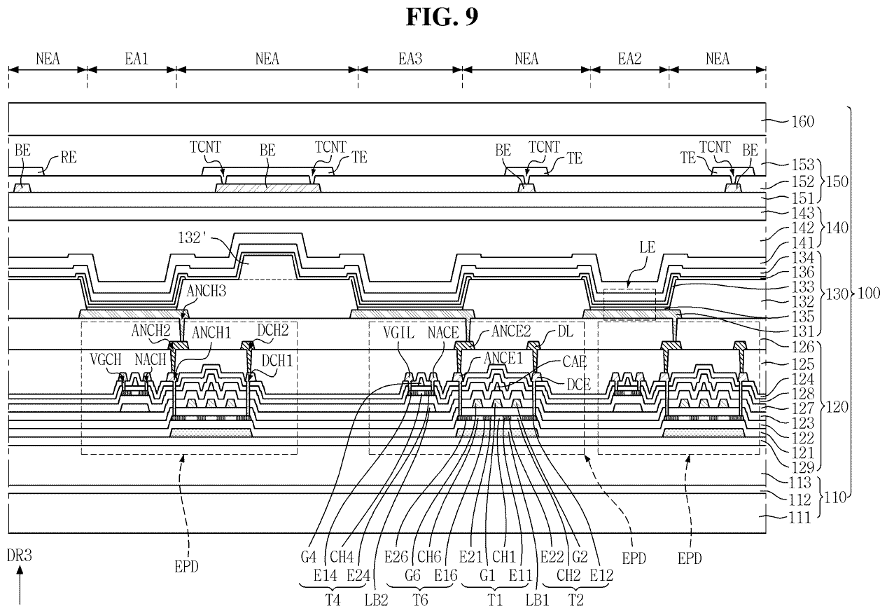

According to embodiments, the display panel 100 may further include a polarization layer 160 (see FIGS. 7, 9 for example) on the touch sensor layer 150.

The polarization layer 160 blocks external light reflected from the touch sensor layer 150, the encapsulation layer 140, the element layer 130, and the circuit layer 120, and the interfaces thereof, and this is to prevent the deterioration of visibility of an image due to external light reflection.

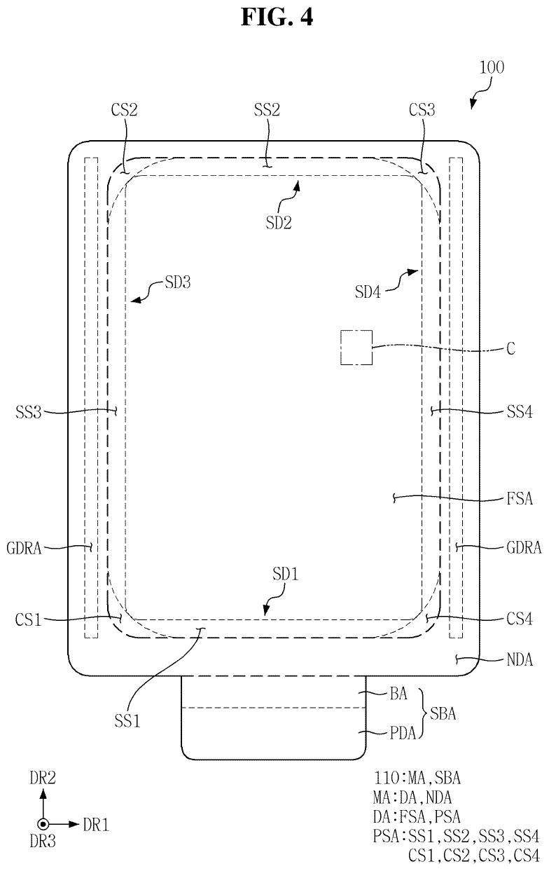

FIG. 4 is a plan view showing the substrate 110 of FIG. 3. FIG. 5 is a layout diagram illustrating part C of FIG. 4.

Referring to FIG. 4, the display panel 100 of the display device 10 according to embodiments may include the substrate 110.

The substrate 110 may include the main region MA corresponding to the display surface, and the sub-region SBA protruding from one side of the main region MA.

The main region MA may include the display area DA from which light is emitted, and the non-display area NDA which is disposed around the display area DA and from which no light is emitted.

Referring to FIG. 5, the emission areas EA, which emit light with respective colors and luminances for image display, may be arranged in the display area DA.

The display area DA may further include a non-emission area disposed in a gap between the emission areas EA.

The emission areas EA may have a rhombus shape or a rectangular shape in plan view. However, this is only an example, and the planar shape of the emission areas EA according to an embodiment is not limited to that illustrated in FIG. 5. That is, in plan view, the emission areas EA may have a polygonal shape such as a square, a pentagon, a hexagon, etc., or may have a circular or elliptical shape including the edge of a curve.

The emission areas EA may include first emission areas EA1 emitting light of a first color in a predetermined wavelength band, second emission areas EA2 emitting light of a second color in a wavelength band lower than that of the first color, and third emission areas EA3 emitting light of a third color in a wavelength band lower than that of the second color.

For example, the first color may be red having a wavelength band of approximately 600 nm to 750 nm. The second color may be green having a wavelength band of approximately 480 nm to 560 nm. The third color may be blue having a wavelength band of approximately 370 nm to 460 nm.

The first emission areas EA1 and the third emission areas EA3 may be alternately arranged in at least one of the first direction DR1 or the second direction DR2.

The second emission areas EA2 may be arranged side by side in at least one of the first direction DR1 or the second direction DR2.

In addition, the second emission areas EA2 may be adjacent to the first emission areas EA1 and the third emission areas EA3 in diagonal directions DR4 and DR5 intersecting the first direction DR1 and the second direction DR2.

Pixels PX displaying their own luminances and colors may be provided by the first emission area EA1, the second emission area EA2, and the third emission area EA3 adjacent to each other among these emission areas EA.

In other words, the pixels PX may be a basic unit for displaying various colors including white with a predetermined luminance.

Each of the pixels PX may include at least one first emission area EA1, at least one second emission area EA2, and at least one third emission area EA3 that are adjacent to each other. Accordingly, each of the pixels PX may display various colors through a mixture of the light emitted from the first emission area EA1, the second emission area EA2, and the third emission area EA3 that are adjacent to each other.

As shown in FIG. 4, the display area DA of the substrate 110 of the display panel 10 according to embodiments may include the front display area FSA in the center and the peripheral display area PSA disposed around the front display area FSA.

The front display area FSA may maintain a flat shape on a plane defined by the first direction DR1 and the second direction DR2.

The front display area FSA may include the first side SD1 and the second side SD2 that extend in the first direction DR1 and are opposite to each other, and the third side SD3 and the fourth side SD4 that extend in the second direction DR2, make connection between the first side SD1 and the second side SD2, and are opposite to each other.

The peripheral display area PSA may be disposed between the front display area FSA and the non-display area NDA. The peripheral display area PSA may have a ring shape surrounding the periphery of the front display area FSA.

As shown in FIGS. 1 and 2, the peripheral display area PSA may be transformed into a curved shape.

As shown in FIG. 4, the peripheral display area PSA may include: the first side area SS1, the second side area SS2, the third side area SS3, and the fourth side area SS4 which are in contact with the first side SD1, the second side SD2, the third side SD3, and the fourth side SD4 of the front display area FSA, respectively. The peripheral display area PSA may further include the first corner area CS1 that is in contact with a vertex where the first side SD1 and the third side SD3 meet and is disposed between the first side area SS1 and the third side area SS3; the second corner area CS2 that is in contact with a vertex where the second side SD2 and the third side SD3 meet and is disposed between the second side area SS2 and the third side area SS3; the third corner area CS3 that is in contact with a vertex where the second side SD2 and the fourth side SD4 meet and is disposed between the second side area SS2 and the fourth side area SS4; and the fourth corner area CS4 that is in contact with a vertex where the first side SD1 and the fourth side SD4 meet and is disposed between the first side area SS1 and the fourth side area SS4.

Hereinafter, for simplicity of description, the first side area SS1, the second side area SS2, the third side area SS3, and the fourth side area SS4 may be collectively referred to as side areas, and these side areas are parallel to sides of the edge of the substrate 110, sometimes called the edge sides of the substrate 110. Further, the first corner area CS1, the second corner area CS2, the third corner area CS3, and the fourth corner area CS4 may be collectively referred to as corner areas.

The non-display area NDA may be disposed at the edge of the main region MA and may be a ring shape surrounding the display area DA.

The non-display area NDA may include a gate driving circuit area GDRA where a gate driving circuit is disposed.

The gate driving circuit may supply signals to gate lines of the circuit layer 120. Each of the gate lines may be electrically connected to a gate electrode of at least one of transistors of the light emitting pixel drivers EPD.

According to an embodiment of FIG. 6, the gate lines may include a scan write line GWL for transmitting a scan write signal GW, a scan initialization line GIL for transmitting a scan initialization signal GI, an emission control line ECL for transmitting an emission control signal EC, and a gate control line GCL for transmitting a gate control signal GC.

In addition, according to an embodiment of FIG. 8, the gate lines may further include a bias control line GBL for transmitting a bias control signal GB.

The gate driving circuit area GDRA may face one side of the edge of the display area DA extending in the second direction DR2.

In one example, the non-display area NDA may include two gate driving circuit areas GDRA that respectively face a pair of sides of the edge of the display area DA extending in the second direction DR2.

The sub-region SBA may face the first side SD1 of the front display area FSA.

The sub-region SBA may include a bending area BA, which is transformed into a bent shape, and the pad area PDA, which is connected to the bending area BA.

When the main region MA has a shape similar to the front display area FSA, the edge of the main region MA may include four sides, and four corners where two sides extending in different directions are connected.

That is, the edge of the main region MA may have two sides extending in the first direction DR1 and opposite to each other, and two sides extending in the second direction DR2 and opposite to each other.

The corners of the main region MA may have an arc shape or a right-angled vertex shape.

However, the shape of the main region MA according to embodiments is not limited to the quadrangle shown in FIG. 4, and may be a circle, an ellipse, or a polygon other than the quadrangle.

FIG. 6 is an equivalent circuit diagram showing the light emitting pixel driver EPD of FIG. 5 according to an embodiment.

Referring to FIG. 6, the light emitting pixel drivers EPD of the circuit layer 120 may be electrically connected between a first power ELVDD and the light emitting elements LE of the element layer 130. One of the light emitting elements LE of the element layer 130 may be electrically connected between one of the light emitting pixel drivers EPD of the circuit layer 120 and a second power ELVSS.

That is, the anode electrode of the light emitting element LE is electrically connected to the light emitting pixel driver EPD, and the cathode electrode of the light emitting element LE may be applied with the second power ELVSS from a second power line VSL lower than the first power ELVDD.

A capacitor Cel connected in parallel with the light emitting element LE refers to a parasitic capacitance between the anode electrode and the cathode electrode.

The circuit layer 120 may include a first power line VDL for transmitting the first power ELVDD, a gate initialization voltage line VGIL for transmitting a gate initialization voltage VGINT, and an anode initialization voltage line VAIL for transmitting an anode initialization voltage VAINT.

The circuit layer 120 may further include the scan write line GWL for transmitting a scan write signal GW, the scan initialization line GIL for transmitting the scan initialization signal GI, the emission control line ECL for transmitting the emission control signal EC, and the gate control line GCL for transmitting the gate control signal GC.

The scan write line GWL, the scan initialization line GIL, the emission control line ECL, and the gate control line GCL are electrically connected to the gate electrodes of second to seventh transistors T2 to T7, and thus may be collectively referred to as the gate lines in the following.

The circuit layer 120 may further include the gate driving circuit disposed in the gate driving circuit area GDRA of the non-display area NDA (see FIG. 4) and supplying signals to the gate lines GWL, GIL, ECL, and GCL.

One light emitting pixel driver EPD of the circuit layer 120 may include a first transistor T1 configured to generate a driving current for driving the light emitting element LE, two or more of the transistors T2 to T7 electrically connected to the first transistor T1, and at least one capacitor PC1.

The first transistor T1 may be electrically connected between the first node N1 and the second node N2. The first node N1 is electrically connected to the first electrode (e.g., source electrode) of the first transistor T1. The second node N2 is electrically connected to the second electrode (e.g., drain electrode) of the first transistor T1.

The first node N1 may be electrically connected to the first power line VDL through the fifth transistor T5.

The second node N2 may be electrically connected to the anode electrode of the light emitting element LE through the sixth transistor T6.

The first capacitor PC1 may be electrically connected between the first power line VDL and a third node N3. The third node N3 is electrically connected to the gate electrode of the first transistor T1.

That is, the gate electrode of the first transistor T1 may be electrically connected to the first power line VDL through the first capacitor PC1.

Accordingly, the potential of the gate electrode of the first transistor T1 may be maintained at the voltage charged in the first capacitor PC1.

The second transistor T2 may be electrically connected between the data line DL and the first node N1.

The second transistor T2 may be electrically connected between the first electrode of the first transistor T1 and the data line DL.

That is, the first electrode of the first transistor T1 may be electrically connected to the data line DL through the second transistor T2.

The second transistor T2 may be turned on by the scan write signal GW of the scan write line GWL.

The fifth transistor T5 may be electrically connected between the first node N1 and the first power line VDL.

The sixth transistor T6 may be electrically connected between the second node N2 and a fourth node N4. The fourth node N4 is electrically connected to the anode electrode of the light emitting element LE.

That is, the fifth transistor T5 may be electrically connected between the first electrode of the first transistor T1 and the first power line VDL.

The sixth transistor T6 may be electrically connected between the second electrode of the first transistor T1 and the anode electrode of the light emitting element LE.

The fifth transistor T5 and the sixth transistor T6 may be turned on by the emission control signal EC of the emission control line ECL.

When the data signal Vdata of the data line DL is transmitted to the first electrode of the first transistor T1 through the turned-on second transistor T2, the voltage difference between the gate electrode of the first transistor T1 and the first electrode of the first transistor T1 may be a difference voltage between the first power ELVDD and the data signal Vdata.

In this case, when the voltage difference between the gate electrode of the first transistor T1 and the first electrode of the first transistor T1, i.e., the gate-source voltage difference becomes equal to or greater than a threshold voltage, the first transistor T1 may be turned on, thereby generating a drain-source current of the first transistor T1 corresponding to the data signal Vdata.

Subsequently, when the fifth transistor T5 and the sixth transistor T6 are turned on, the first power ELVDD, the first transistor T1, the light emitting element LE, and the second power ELVSS may be connected in series. Accordingly, the drain-source current of the first transistor T1 corresponding to the data signal Vdata may be supplied as a driving current of the light emitting element LE.

Accordingly, the light emitting element LE may emit light having a luminance corresponding to the data signal Vdata.

The third transistor T3 may be electrically connected between the second node N2 and the third node N3. That is, the third transistor T3 may be electrically connected between the gate electrode of the first transistor T1 and the second electrode of the first transistor T1.

The third transistor T3 may include a plurality of sub-transistors connected in series. For example, the third transistor T3 may include a first sub-transistor T31 and a second sub-transistor T32.

The first electrode of the first sub-transistor T31 may be connected to the gate electrode of the first transistor T1, the second electrode of the first sub-transistor T31 may be connected to the first electrode of the second sub-transistor T32, and the second electrode of the second sub-transistor T32 may be connected to the second electrode of the first transistor T1.

In this way, it is possible to prevent the potential of the gate electrode of the first transistor T1 from changing due to the leakage current caused by the third transistor T3 that is not turned on.

The first sub-transistor T31 and the second sub-transistor T32 may be turned on by the scan write signal GW of the scan write line GWL.

When the first sub-transistor T31 and the second sub-transistor T32 are turned on, the voltage difference between the second node N2 and the third node N3 may be initialized.

The fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may include a plurality of sub-transistors connected in series. For example, the fourth transistor T4 may include a third sub-transistor T41 and a fourth sub-transistor T42. The first electrode of the third sub-transistor T41 may be connected to the gate

electrode of the first transistor T1, the second electrode of the third sub-transistor T41 may be connected to the first electrode of the fourth sub-transistor T42, and the second electrode of the fourth sub-transistor T42 may be connected to the gate initialization voltage line VGIL.

In this way, it is possible to prevent the potential of the gate electrode of the first transistor T1 from changing due to the leakage current caused by the fourth transistor T4 that is not turned on.

The third sub-transistor T41 and the fourth sub-transistor T42 may be turned on by the scan initialization signal GI of the scan initialization line GIL.

When the third sub-transistor T41 and the fourth sub-transistor T42 are turned on, the potential of the third node N3 may be initialized to the gate initialization voltage VGINT.

The seventh transistor T7 may be electrically connected between the fourth node N4 and the anode initialization voltage line VAIL. That is, the seventh transistor T7 may be electrically connected between the anode electrode of the light emitting element LE and the anode initialization voltage line VAIL.

The seventh transistor T7 may be turned on by the gate control signal GC of the gate control line GCL.

Through the turned-on seventh transistor T7, the potential of the fourth node N4 may be initialized to the anode initialization voltage VAINT.

As shown in FIG. 6, according to an embodiment, the first to seventh transistors T1 to T7 may be provided as P-type MOSFETs.

FIG. 7 is a cross-sectional view illustrating a light emitting element LE, a first transistor T1, and a sixth transistor T6 of the light emitting pixel driver EPD according to an embodiment of FIG. 6.

Referring to FIG. 7, the display panel 100 of the display device 10 according to embodiments may include the substrate 110, the circuit layer 120 on the substrate 110, and the element layer 130 on the circuit layer 120.

The display panel 100 of the display device 10 according to embodiments may further include the encapsulation layer 140 on the element layer 130, the touch sensor layer 150 on the encapsulation layer 140, and the polarization layer 160 on the touch sensor layer 150.

According to embodiments, the substrate 110 may include a first support layer 111, a barrier layer 112 disposed on the first support layer 111, and a second support layer 113 disposed on the barrier layer 112.

Each of the first support layer 111 and the second support layer 113 may contain an organic insulating material that can be easily disposed with a thickness sufficient to buffer an external foreign substance. In one example, each of the first support layer 111 and the second support layer 113 may contain polyimide (PI).

The barrier layer 112 may contain an inorganic insulating material different from that of the first support layer 111 and the second support layer 113, to prevent permeation of oxygen or moisture through the substrate 110.

The circuit layer 120 may include a semiconductor layer CH1, E11, E21, CH6, E16, and E26 disposed on the substrate 110, a first gate insulating layer 122 covering the first semiconductor layer, a first gate conductive layer G1 and G6 disposed on the first gate insulating layer 122, a second gate insulating layer 123 covering the first gate conductive layer, a second gate conductive layer CAE disposed on the second gate insulating layer 123, an interlayer insulating layer 124 disposed on the second gate conductive layer CAE, a first source-drain conductive layer ANCE1 disposed on the interlayer insulating layer 124, a first planarization layer 125 covering the first source-drain conductive layer, a second source-drain conductive layer ANCE2 disposed on the first planarization layer 125, and a second planarization layer 126 covering the second source-drain conductive layer.

According to an embodiment, the interlayer insulating layer 124 may be disposed on the second gate insulating layer 123 and cover the second gate conductive layer.

The circuit layer 120 may further include the buffer layer 121 covering the substrate 110.

In this case, the first semiconductor layer CH1, E11, E21, CH6, E16, and E26 may be disposed on the buffer layer 121.

The circuit layer 120 may include the light emitting pixel drivers EPD respectively corresponding to the emission areas EA.

Each of the light emitting pixel drivers EPD may include the first transistor T1, the second to seventh transistors T2 to T7 (see FIG. 8) electrically connected to the first transistor T1, and at least one capacitor PC1 (see FIG. 6).

The first semiconductor layer on the buffer layer 121 may include channel portions CH1 and CH6, first electrode portions E11 and E16, and second electrode portions E21 and E26 of each of the first to seventh transistors T1 to T7.

That is, the channel portions CHI and CH6, the first electrode portions E11 and E16, and the second electrode portions E21 and E26 of the first transistor T1 and the sixth transistor T6 may be disposed as the first semiconductor layer on the buffer layer 121.

In each of the first transistor T1 and the sixth transistor T6, the first electrode portions E11 and E16 may be connected to one end of the channel portions CHI and CH6, and the second electrode portions E21 and E26 may be connected to the other end of the channel portions CH1 and CH6.

The second electrode portion E21 of the first transistor T1 may be connected to the first electrode portion E16 of the sixth transistor T6.

The first gate conductive layer on the first gate insulating layer 122 may include the gate electrodes G1 and G6 of each of the first transistor T1 and the sixth transistor T6.

That is, the gate electrodes G1 and G6 of the first transistor T1 and the sixth transistor T6 may be disposed as the first gate conductive layer on the first gate insulating layer 122.

In the first transistor Tl and the sixth transistor T6, the gate electrodes G1 and G6 may overlap the channel portions CH1 and CH6, respectively.

In the light emitting pixel driver EPD of FIG. 6, the second transistor T2, the first sub-transistor T31, the second sub-transistor T32, the third sub-transistor T41, the fourth sub-transistor T42, the fifth transistor T5, and the seventh transistor T7 are provided as the same P-type MOSFET as the first and sixth transistors T1 and T6, and therefore redundant description thereof will be omitted below.

The second gate conductive layer on the second gate insulating layer 124 may include the capacitor electrode CAE.

The capacitor electrode CAE may overlap the gate electrode G1 of the first transistor T1.

Accordingly, the first capacitor PC1 (see FIG. 6) may be provided by the overlapping area between the capacitor electrode CAE and the gate electrode G1 of the first transistor T1.

The first source-drain conductive layer on the interlayer insulating layer 124 may include the first anode connection electrode ANCE1.

The first anode connection electrode ANCE1 may be electrically connected to the second electrode portion E26 of the sixth transistor T6 through a first anode connection hole ANCH1.

The second source-drain conductive layer on the first planarization layer 128 may include the second anode connection electrode ANCE2.

The second anode connection electrode ANCE2 may be electrically connected to the first anode connection electrode ANCE1 through a second anode connection hole ANCH2.

The anode electrode 131 of the element layer 130 may be disposed on the second planarization layer 126, and may be electrically connected to the second anode connection electrode ANCE2 through a third anode connection hole ANCH3.

Accordingly, the anode electrode 131 may be electrically connected to the second electrode portion E26 of the sixth transistor T6 through the first anode connection electrode ANCE1 and the second anode connection electrode ANCE2.

The element layer 130 on the circuit layer 120 may include the light emitting elements LE respectively disposed in the emission areas EA1, EA2, and EA3.

Each of the light emitting elements LE may include a structure in which a light emitting layer 133 is disposed between the anode electrode 131 and a cathode electrode 134 facing each other.

In an embodiment, each of the light emitting elements LE may further include first common layers 135 disposed between the anode electrodes 131 and the light emitting layers 133, and a second common layer 136 disposed between the light emitting layers 133 and the cathode electrode 134.

That is, according to embodiments, the element layer 130 may include the anode electrodes 131 respectively disposed in the emission areas EA, a pixel defining layer 132 disposed in the non-emission area NEA and covering the edge of the anode electrode 131, a spacer layer 132′ disposed on a part of the pixel defining layer 132, the first common layers 135 respectively disposed on the anode electrodes 131, the light emitting layers 133 respectively disposed on the first common layers 135, a second common layer 136 disposed on the light emitting layers 133, the pixel defining layer 132, and the spacer layer 132′, and the cathode electrode 134 disposed on the second common layer 136.

The encapsulation layer 140 may be disposed on the circuit layer 120 and cover the element layer 130.

The encapsulation layer 140 is to block the permeation of oxygen or moisture into the element layer 130 and to reduce electrical or physical impact to the circuit layer 120 and the element layer 130.

The encapsulation layer 140 may include a first encapsulation layer 141 disposed on the circuit layer 120, covering the element layer 130, and including an inorganic insulating material, a second encapsulation layer 142 disposed on the first encapsulation layer 141, overlapping the element layer 130, and including an organic insulating material, and a third encapsulation layer 143 disposed on the first encapsulation layer 141, covering the second encapsulation layer 142, and including an inorganic insulating material.

The touch sensor layer 150 may be disposed on the encapsulation layer 140.

The touch sensor layer 150 may include driving electrodes TE and sensing electrodes RE spaced apart from each other, and a bridge electrode BE electrically connecting the adjacent driving electrodes TE to each other.

The touch sensor layer 150 may include a touch buffer layer 151 disposed on the encapsulation layer 140, a first touch conductive layer disposed on the touch buffer layer 151, a touch interlayer insulating layer 152 covering the first touch conductive layer, a second touch conductive layer disposed on the touch interlayer insulating layer 152, and a touch planarization layer 153 covering the second touch conductive layer.

The bridge electrode BE may be disposed on a different touch conductive layer from the driving electrodes TE and the sensing electrodes RE.

As an example, the bridge electrode BE may be disposed as the first touch conductive layer on the touch buffer layer 151.

The driving electrodes TE and the sensing electrodes RE may be disposed as the second touch conductive layer on the touch interlayer insulating layer 152.

The driving electrode TE may be electrically connected to the bridge electrode BE through a touch electrode connection hole TCNT penetrating the touch interlayer insulating layer 152.

The touch buffer layer 151 may include an inorganic insulating material.

According to an embodiment, each of the touch interlayer insulating layer 152 and the touch planarization layer 153 may include an organic insulating material.

In an embodiment, the touch interlayer insulating layer 152 may include an inorganic insulating material.

The polarization layer 160 may be disposed on the touch sensor layer 150.

The light emitting pixel driver EPD of FIG. 6 includes the first to seventh transistors T1 to T7 provided as P-type MOSFETs. However, this is merely an example, and some of the first to seventh transistors T1 to T7 may be provided as N-type MOSFETs. For example, the third transistor T3 and the fourth transistor T4 may be provided as N-type MOSFETs.

FIG. 8 is an equivalent circuit diagram showing the light emitting pixel driver of FIG. 5 according to an embodiment.

The circuit layer 120 of the display panel 100 according to an embodiment of FIG. 8 is substantially the same as that of an embodiment shown in FIG. 6, except that the third and fourth transistors T3 and T4 among the first to seventh transistors T1 to T7 of the light emitting pixel driver EPD are provided as N-type MOSFETs, and therefore redundant description thereof will be omitted below.

According to an embodiment of FIG. 8, the third transistor T3 may be electrically connected between the second node N2 and the third node N3. That is, the third transistor T3 may be electrically connected between the gate electrode of the first transistor Tl and the second electrode of the first transistor T1.

As the third transistor T3 is provided as an N-type MOSFET, it may be turned on by the gate control signal GC from the gate control line GCL.

Through the turned-on third transistor T3, the voltage difference between the second node N2 and the third node N3 may be initialized.

The fourth transistor T4 may be electrically connected between the gate initialization voltage line VGIL and the third node N3. That is, the fourth transistor T4 may be connected between the gate electrode of the first transistor T1 and the gate initialization voltage line VGIL.

The fourth transistor T4 may be turned on by the scan initialization signal GI of the scan initialization line GIL.

The potential of the third node N3 may be initialized through the turned-on fourth transistor T4.

As the fourth transistor T4 is provided as an N-type MOSFET, the seventh transistor T7 may be turned on by the bias control signal GB of the bias control line GBL, rather than by the scan initialization signal GI of the scan initialization line GIL.

Since the bias control line GBL is electrically connected to the gate electrode of the seventh transistor T7, it may be collectively referred to as the gate line GL together with the scan write line GWL, the scan initialization line GIL, the emission control line ECL, and the gate control line GCL in the following.

FIG. 9 is a cross-sectional view showing a light emitting element LE, a first transistor T1, a second transistor T2, a fourth transistor T4, and a sixth transistor T6 of the light emitting pixel driver EPD according to an embodiment of FIG. 8.

The circuit layer 120 of the display panel 100 according to an embodiment shown in FIG. 9 is substantially the same as the circuit layer 120 of an embodiment shown in FIG. 7, except that it further includes a second semiconductor layer CH4, E14, and E24, a third gate conductive layer G4, an auxiliary interlayer insulating layer 127, and a third gate insulating layer 128 for providing an N-type MOSFET, and therefore redundant description thereof will be omitted below.

According to an embodiment of FIG. 9, the circuit layer 120 may further include the auxiliary interlayer insulating layer 127 covering the second gate conductive layer, the second semiconductor layer CH4, E14, and E24 disposed on the auxiliary interlayer insulating layer 127, the third gate insulating layer 128 covering the second semiconductor layer, and the third gate conductive layer G4 disposed on the third gate insulating layer 128 and covered with the interlayer insulating layer 124.

In addition, according to an embodiment of FIG. 9, the circuit layer 120 may further include a barrier layer 129 disposed on the substrate 110, and a first light blocking layer LB1 disposed on the barrier layer 129 and covered with the buffer layer 121.

In other words, according to an embodiment of FIG. 9, the circuit layer 120 may include the barrier layer 129 disposed on the substrate 110, the first light blocking layer LB1 disposed on the barrier layer 129, the buffer layer 121 covering the first light blocking layer LB1, the first semiconductor layer CH1, E11, E21, CH2, E12, E22, CH6, E16, and E26 disposed on the buffer layer 121, the first gate insulating layer 122 covering the first semiconductor layer, the first gate conductive layer G1, G2, and G6 disposed on the first gate insulating layer 122, the second gate insulating layer 123 covering the first gate conductive layer, the second gate conductive layer CAE and LB2 disposed on the second gate insulating layer 123, the auxiliary interlayer insulating layer 127 covering the second gate conductive layer, the second semiconductor layer CH4, E14, and E24 disposed on the auxiliary interlayer insulating layer 127, the third gate insulating layer 128 covering the second semiconductor layer, the third gate conductive layer G4 disposed on the third gate insulating layer 126 and covered with the interlayer insulating layer 124, the interlayer insulating layer 124 covering the third gate conductive layer, the first source-drain conductive layer ANCE1, VGIL, and DCE disposed on the interlayer insulating layer 124, the first planarization layer 125 covering the first source-drain conductive layer, the second source-drain conductive layer DL and ANCE2 disposed on the first planarization layer 125, and the second planarization layer 126 covering the second source-drain conductive layer.

The first semiconductor layer on the buffer layer 121 may include the channel portions CH1, CH2, and CH6, the first electrode portions E11, E12, and E16, and the second electrode portions E21, E22, and E26 of the first transistor T1, the second transistor T2, the fifth transistor T5 (see FIG. 8), the sixth transistor T6, and the seventh transistor T7 (see FIG. 8) that are provided as P-type MOSFETs.

The first gate conductive layer on the first gate insulating layer 122 may include the gate electrodes G1, G2, and G6 of the first transistor T1, the second transistor T2, the fifth transistor T5 (see FIG. 8), the sixth transistor T6, and the seventh transistor T7 (see FIG. 8) that are provided as P-type MOSFETs.

Since the fifth transistor T5 and the seventh transistor T7 have the same structure as those of the first transistor T1, the second transistor T2, and the sixth transistor T6, the redundant description will be omitted below.

In each of the first transistor T1, the second transistor T2, and the sixth transistor T6, the channel portions CH1, CH2, and CH6 may overlap the gate electrodes G1, G2, and G6.

The channel portion CHI of the first transistor T1 may overlap the first light blocking layer LB1 below the buffer layer 121.

In each of the first transistor T1, the second transistor T2, and the sixth transistor T6, the first electrode portions E11, E12, and E16 may be connected to one end of the channel portions CH1, CH2, and CH6, and the second electrode portions E21, E22, and E26 may be connected to the other end of the channel portions CH1, CH2, and CH6.

The first electrode portion E11 of the first transistor T1 may be connected to the second electrode portion E22 of the second transistor T2.

The second electrode portion E21 of the first transistor T1 may be connected to the first electrode portion E16 of the sixth transistor T6.

The second gate conductive layer on the second gate insulating layer 123 may include the capacitor electrode CAE and the second light blocking layer LB2.

The second semiconductor layer on the auxiliary interlayer insulating layer 127 may include the channel portion CH4, the first electrode portion E14, and the second electrode portion E24 of each of the third transistor T3 (see FIG. 8) and the fourth transistor T4 that are provided as N-type MOSFETs.

The third gate conductive layer on the third gate insulating layer 128 may include the gate electrode G4 of each of the third transistor T3 (see FIG. 8) and the fourth transistor T4 that are provided as N-type MOSFETs.

In each of the third transistor T3 (see FIG. 8) and the fourth transistor T4, the channel portion CH4 may overlap the second light blocking layer LB2 below the auxiliary interlayer insulating layer 127.

The channel portion CH4 of the fourth transistor T4 may overlap the gate electrode G4 of the fourth transistor T4.

The first electrode portion E14 of the fourth transistor T4 may be connected to one end of the channel portion CH4 of the fourth transistor T4, and the second electrode portion E24 of the fourth transistor T4 may be connected to the other end of the channel portion CH4 of the fourth transistor T4.

Since the third transistor T3 is provided as the same N-type MOSFET as the fourth transistor T4, redundant description thereof will be omitted below.

The first source-drain conductive layer on the interlayer insulating layer 124 may include the first anode connection electrode ANCE1, the data connection electrode DCE, the gate initialization voltage line VGIL, and a node auxiliary connection electrode NACE.

The second source-drain conductive layer on the first planarization layer 125 may include the second anode connection electrode ANCE2 and the data line DL.

The data connection electrode DCE may be electrically connected to the first electrode portion E12 of the second transistor T2 through a first data connection hole DCH1.

The data line DL may be electrically connected to the data connection electrode DCE through a second data connection hole DCH2.

Accordingly, the data line DL may be electrically connected to the first electrode portion E12 of the second transistor T2 through the data connection electrode DCE.

The gate initialization voltage line VGIL may be electrically connected to the first electrode portion E14 of the fourth transistor T4 through a gate initialization voltage connection hole VGCH.

The node auxiliary connection electrode NACE may be electrically connected to the second electrode portion E24 of the fourth transistor T4 through a node auxiliary connection hole NACH.

The element layer 130, the encapsulation layer 140, the touch sensor layer 150, and the polarization layer 160 of the display panel 100 according to an embodiment shown in FIG. 9 are substantially the same as those of an embodiment shown in FIG. 7, and therefore redundant description thereof will be omitted below.

The display panel 100 according to embodiments is transformed such that the peripheral display area PSA of the edge of the display area DA is curved. As a result, bending stress is applied to the peripheral display area PSA, and in particular, relatively excessive bending stress may be applied to the corner areas CS1, CS2, CS3, and CS4, which are the double curvature regions of the peripheral display area PSA, thereby causing defects to occur easily.

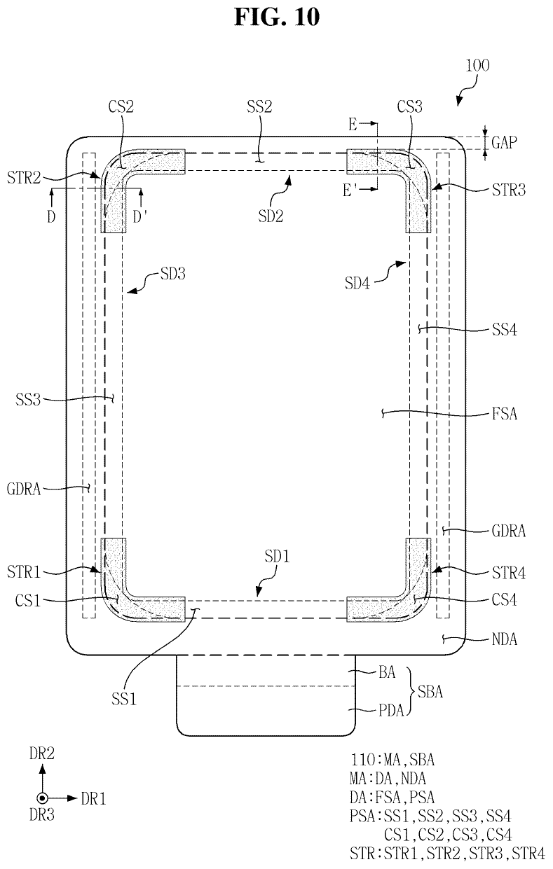

In order to prevent this, according to embodiments, the display panel 100 may further include a strain adjustment part STR (see FIG. 10) that overlaps at least the corner areas CS1, CS2, CS3, and CS4 of the peripheral display area PSA.

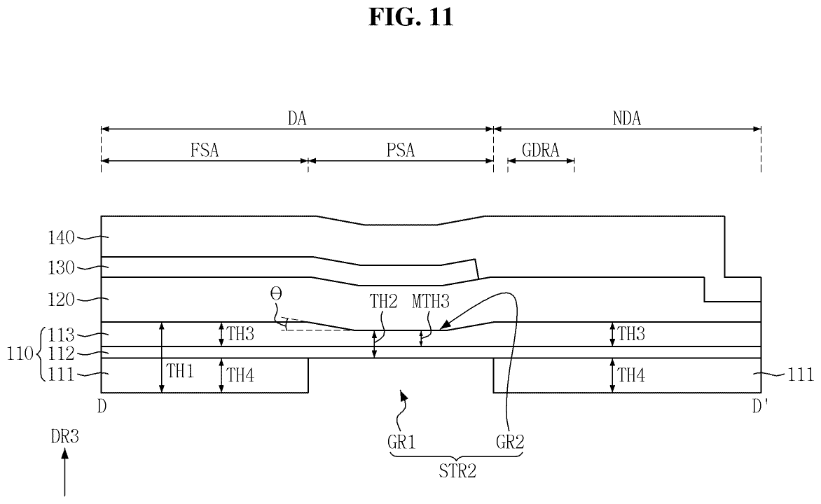

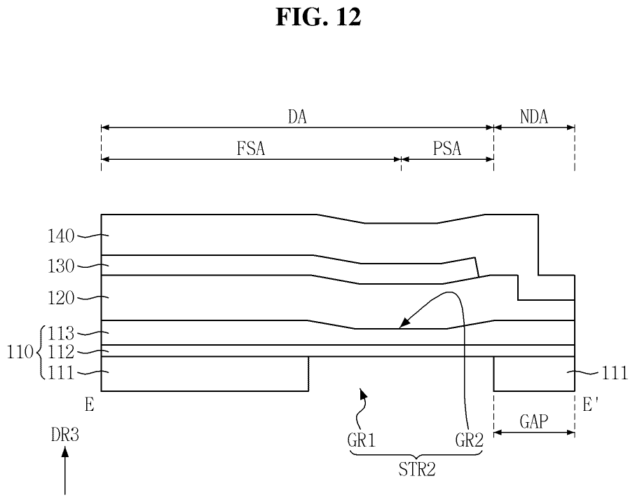

FIG. 10 is a plan view illustrating a display panel 100 according to embodiments. FIG. 11 is a cross-sectional view taken along line D-D′ of FIG. 10 according to an embodiment. FIG. 12 is a cross-sectional view taken along line E-E′ of FIG. 10 according to an embodiment.

Referring to FIG. 10, the display panel 100 of the display device 10 according to

embodiments further includes the strain adjustment part STR that overlaps the corner areas CS1, CS2, CS3, and CS4 of the peripheral display area PSA adjacent to the corners of the edge of the substrate 110 and is spaced apart from the edge of the substrate 110.

The strain adjustment part STR may further overlap some portions of the side areas SS1, SS2, SS3, and SS4 of the peripheral display area PSA that are adjacent to the corner areas CS1, CS2, CS3, and CS4.

According to embodiments of FIG. 10, the strain adjustment part STR may include a first strain adjustment part STR1, a second strain adjustment part STR2, a third strain adjustment part STR3, and a fourth strain adjustment part STR4 that overlap the first corner area CS1, the second corner area CS2, the third corner area CS3, and the fourth corner area CS4, respectively.

Referring to FIGS. 11 and 12, the substrate 110 may have a first thickness TH1 in a portion not overlapping the strain adjustment part STR. In addition, a portion of the substrate 110 that overlaps the strain adjustment part STR may have a second thickness TH2 that is smaller than the first thickness TH1 due to the strain adjustment part STR.

In one example, the second thickness TH2 may be 50% or more and 85% or less of the first thickness TH1.

The substrate 110 may include the first support layer 111, the barrier layer 112 disposed on the first support layer 111, and the second support layer 113 disposed on the barrier layer 112.

The strain adjustment part STR may include a first groove GR1 that penetrates at least a part of the first support layer 111, and a second groove GR2 that overlaps the first groove GR1 and penetrates a part of the second support layer 113.

As the circuit layer 120 is disposed on the second support layer 113, the side surface of the second groove GR2 may have a relatively gentle inclination θ relative to the plane of the substrate 110, i.e., relative to the X-Y plane. In one example, the inclination θ of the side surface of the second groove GR2 may be greater than or equal to 5° and less than or equal to 15°.

In this way, defects such as delamination and disconnection in the circuit layer 120 due to the level difference of the second groove GR2 may be prevented.

The second support layer 113 may be disposed with a third thickness TH3 in a portion not overlapping the strain adjustment part STR.

A portion of the second support layer 113 that overlaps the bottom surface of the second groove GR2 has a change thickness MTH3 that is less than the third thickness TH3. Another portion of the second support layer 113 that overlaps the side surface of

the second groove GR2 may have a thickness that gradually varies between the third thickness TH3 and the change thickness MTH3.

The change thickness MTH3 may be 50% or more and 85% or less of the third thickness TH3.

If the change thickness MTH3 is less than 50% of the third thickness TH3, the circuit layer 120 and the element layer 130 on the substrate 110 may be difficult to be stably supported by the strain adjustment part STR, resulting in degradation of the image quality of the corner areas CS1, CS2, CS3, and CS4.

In one example, the change thickness MTH3 may be 3 μm or more.

In addition, if the change thickness MTH3 is greater than 85% of the third thickness TH3, the strain improvement of the substrate 110 by the strain adjustment part STR may be insignificant, so that it may be difficult to achieve an effect of reducing defects caused by excessive bending stress in the double curvature region.

The first support layer 111 may have a fourth thickness TH4 in a portion not overlapping the strain adjustment part STR that is greater than the third thickness TH3.

According to an embodiment, the first groove GR1 may completely penetrate the first support layer 111 and expose the barrier layer 112.

As shown in FIGS. 10 and 11, according to an embodiment, the strain adjustment part STR may limitedly overlap only a part of the peripheral display area PSA including the corner areas CS1, CS2, CS3, and CS4 which are the double curvature regions.

Accordingly, in an embodiment, the strain adjustment part STR may be spaced apart from the gate driving circuit area GDRA of the non-display area NDA.

As described above, according to embodiments, the display panel 100 includes the strain adjustment part STR that overlaps a part of the peripheral display area PSA including the corner areas CS1, CS2, CS3, and CS4 which are the double curvature regions.

As the strain adjustment part STR includes the first groove GR1 penetrating at least a part of the first support layer 111 and the second groove GR2 penetrating a part of the second support layer 112, a portion of the substrate 110 that overlaps the strain adjustment part STR may have the second thickness TH2 less than the first thickness TH1 of another portion not overlapping the strain adjustment part STR, thereby having a higher strain. Accordingly, the occurrence rate of defects due to the bending stress in the double curvature region may be reduced.

As shown in FIGS. 10 and 12, according to embodiments, the strain adjustment part STR is spaced apart from the edge of the substrate 110.

The minimum value of a separation distance GAP between the strain adjustment part STR and the edge of the substrate 110 may be 150 μm to 180 μm.

That is, the strain adjustment part STR may be spaced apart from the edge of the substrate 110 by 150 μm or more.

In other words, since the strain adjustment part STR does not extend to the edge of the substrate 110, the edge of the substrate 110 may be maintained at the first thickness TH1 in the same manner as the front display area FSA. Accordingly, even if the display panel 100 further includes the strain adjustment part STR, the tensile stress at the edge of the substrate 110 may be maintained, thereby preventing curling defects of the edge of the substrate 110.

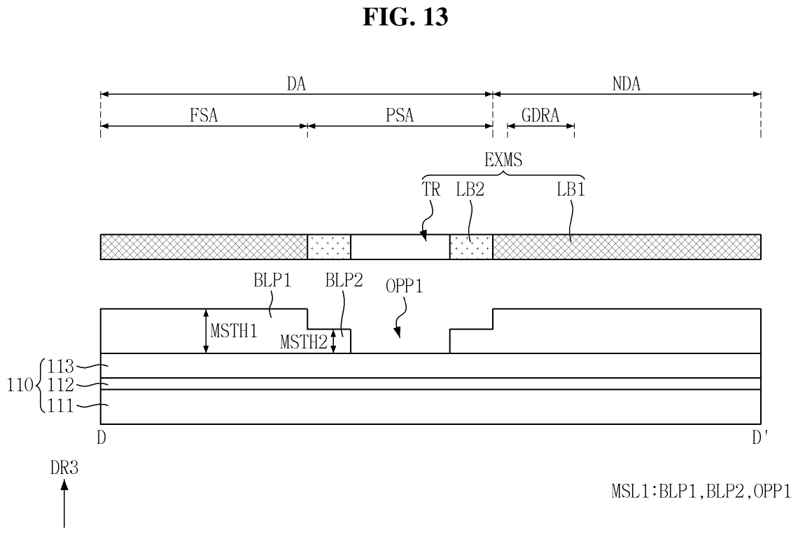

FIGS. 13, 14, 15, 16, and 17 are process diagrams illustrating steps of a process of disposing a strain adjustment part according to embodiments.

Referring to FIGS. 13, 14, 15, 16, and 17, the process of disposing the strain adjustment part STR may include: disposing a first mask layer MSL1 (see FIG. 13) on the substrate 110; partially etching the second support layer 113 through a first open portion OPP1 (see FIG. 13) of the first mask layer MSL1 to form a preliminary groove PGR; ashing the first mask layer MSL1 to prepare a second mask layer MSL2; partially etching the second support layer 113 through the first open portion OPP1 and a second open portion OPP2 of the second mask layer MSL2 to form the second groove GR2; and removing the second mask layer MSL2 and partially etching the first support layer 111 to form the first groove GR1.

Referring to FIG. 13, in the step of disposing the first mask layer MSL1, the first mask layer MSL1 may be prepared by disposing a mask material layer on the second support layer 113 of the substrate 110 and developing the mask material layer differentially exposed through a halftone exposure mask EXMS.

The halftone exposure mask EXMS may include a light blocking portion LB1 that blocks most of light, a semi-transmission portion LB2 that blocks a part of light, and a transmission portion TR that transmits light.

The transmission portion TR may overlap a part of the peripheral display area PSA, and the semi-transmission portion LB2 may be disposed around the transmission portion TR. The light blocking portion LB1 may be disposed in the remaining part except for the transmission portion TR and the semi-transmission portion LB2.

The first mask layer MSL1 may include a first blocking portion BLP1 facing the light blocking portion LB1 and maintained at a first mask thickness MSTH1, a second blocking portion BLP2 facing the semi-transmission portion LB2 and disposed at a second mask thickness MSTH2 less than the first mask thickness MSTH1, and the first open portion OPP1 facing the transmission portion TR and exposing the second support layer 113.

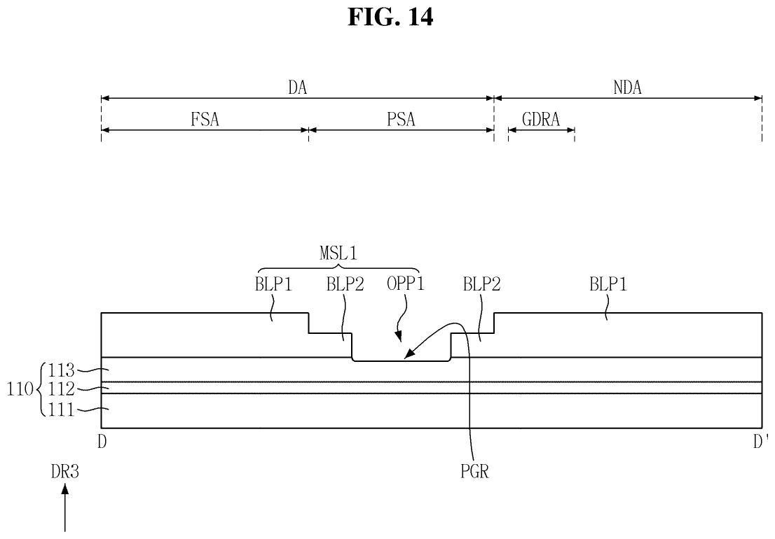

Referring to FIG. 14, in the step of forming the preliminary groove PGR, the preliminary groove PGR may be formed by partially etching a portion of the second support layer 113 exposed through the first open portion OPP1 of the first mask layer MSL1.

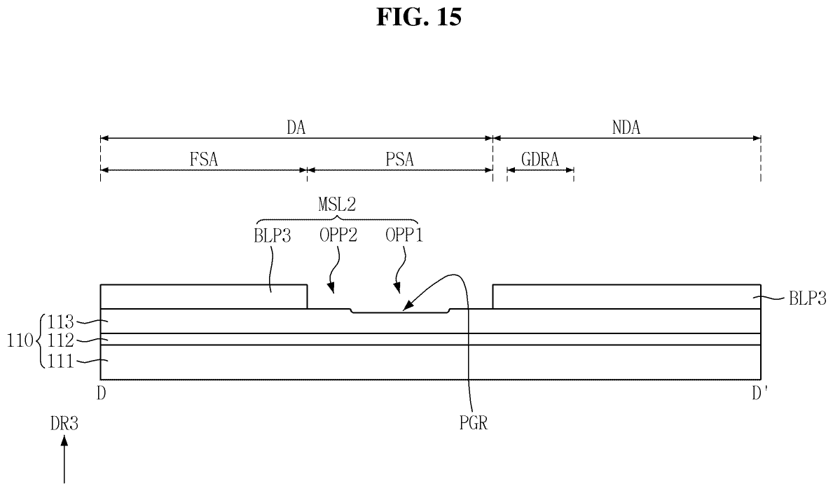

Referring to FIG. 15, in the step of preparing the second mask layer MSL2, the second mask layer MSL2 may be prepared by performing an ashing process until the second blocking portion BLP2 of the first mask layer MSL1 (see FIG. 14) is removed.

The second mask layer MSL2 may include the first open portion OPP1, a third blocking portion BLP3 formed by thinning the first blocking portion BLP1 of the first mask layer MSL1 through the ashing process, and the second open portion OPP2 formed by removing the second blocking portion BLP2 of the first mask layer MSL1 through the ashing process.

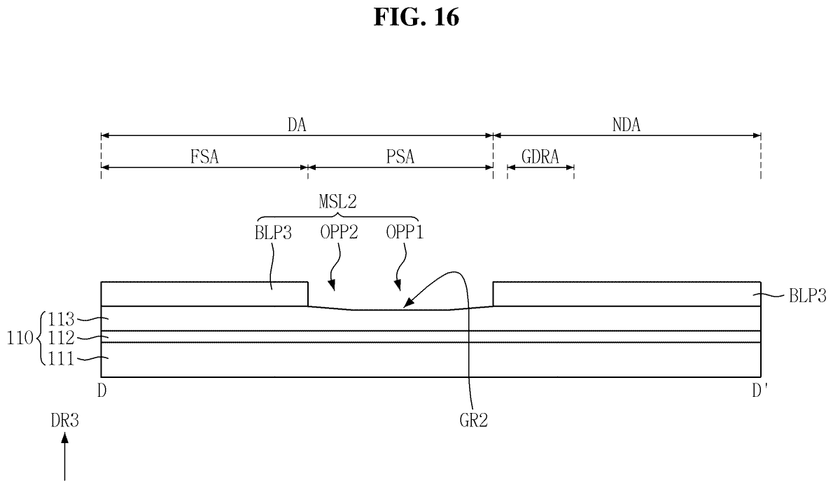

Referring to FIG. 16, in the step of forming the second groove GR2, the second groove GR2 may be formed by partially etching a portion of the second support layer 113 exposed through the first open portion OPP1 and the second open portion OPP2 of the second mask layer MSL2.

In the second open portion OPP2, the second support layer 113 may be easily exposed to an etching material at a position closer to the preliminary groove PGR formed by the first open portion OPP1, while it may be difficult to be exposed to the etching material at a position closer to the third blocking portion BLP3, so that the side surface of the second groove GR2 may have a gentle inclination.

The bottom surface of the second groove GR2 may be a variant of the preliminary groove PGR (see FIG. 14).

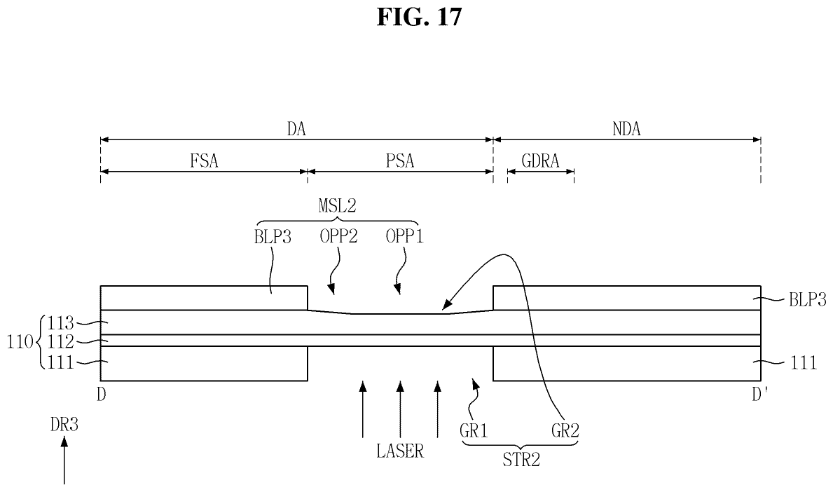

Referring to FIG. 17, in the step of forming the first groove GR1, the first groove GR1 may be formed by partially irradiating a laser LASER to a portion of the first support layer 111 overlapping a part of the peripheral display area PSA to remove a part of the first support layer 111.

Thus, the strain adjustment part STR including the first groove GR1 and the second groove GR2 may be provided.

In the step of forming the first groove GR1, the removal amount of the first support layer 111 may be varied depending on the irradiation amount of the laser LASER. That is, the first groove GR1 may not completely penetrate a part of the first support layer 111, and a residual portion of the first support layer 111 may remain in the first groove GR1.

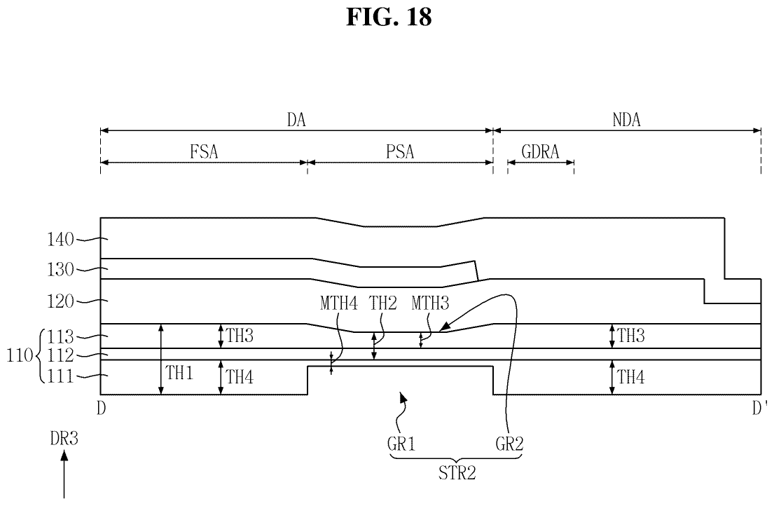

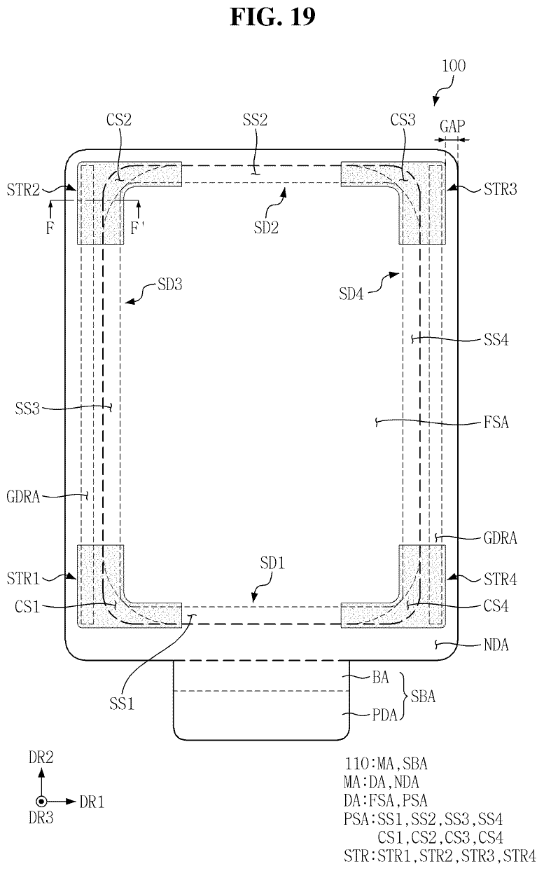

FIG. 18 is a cross-sectional view taken along line D-D′ of FIG. 10 according to an embodiment.

As shown in FIG. 18, the display panel 100 of the display device 10 according to an embodiment is substantially the same as that of an embodiment shown in FIGS. 10, 11, and 12, except that the first groove GR1 of the strain adjustment part STR does not completely penetrate the first support layer 111, and therefore redundant description thereof will be omitted below.

The first support layer 111 may be disposed with the fourth thickness TH4 in a portion not overlapping the strain adjustment part STR that is greater than the third thickness TH3 in a portion not overlapping the strain adjustment part STR of the second support layer 113.

When the first support layer 111 remains in the first groove GR1, a thickness MTH4 of a portion of the first support layer 111 overlapping the first groove GR1 may be 10% or less of the fourth thickness TH4.

When the thickness MTH4 of the portion of the first support layer 111 overlapping the first groove GR1 is greater than 10% of the fourth thickness TH4, the strain improvement of the substrate 110 by the strain adjustment part STR may be insignificant, so that it may be difficult to achieve the effect of reducing defects caused by excessive bending stress in the double curvature region.

According to an embodiment of FIG. 18, since the first support layer 111 remains in the first groove GR1, the barrier layer 112 may be protected from laser irradiation.

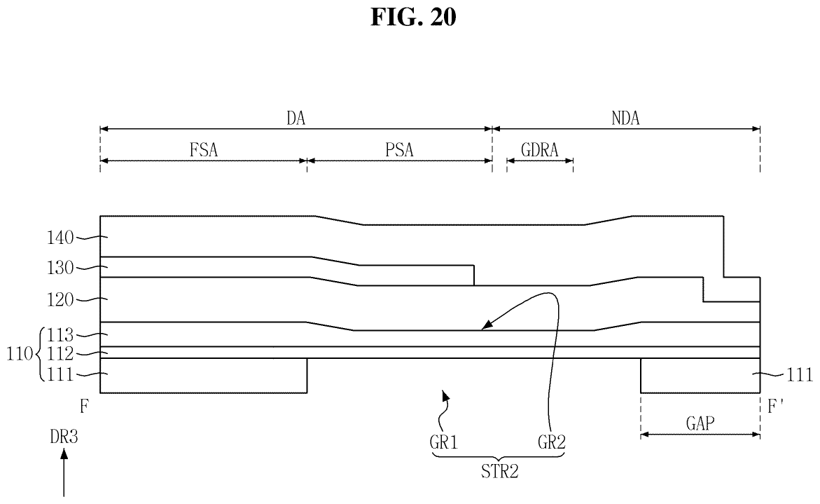

FIG. 19 is a plan view illustrating a display panel 100 according to an embodiment. FIG. 20 is a cross-sectional view taken along line F-F′ of FIG. 19.

The display panel 100 of the display device 10 according to an embodiment shown in FIGS. 19 and 20 is substantially the same as that of embodiments shown in FIGS. 11, 12, 13, and 18, except that the strain adjustment part STR further overlaps some portions of the non-display area NDA adjacent to the corner areas CS1, CS2, CS3, and CS4, and therefore redundant description thereof will be omitted below.

The gate driving circuit area GDRA of the non-display area NDA is disposed adjacent to the display area DA. Therefore, when the strain adjustment part STR extends into a part of the non-display area NDA, the strain adjustment part STR may overlap a part of the gate driving circuit area GDRA.

Further, even when the strain adjustment part STR extends into a part of the non-display area NDA, the strain adjustment part STR is spaced apart from the edge of the substrate 110. That is, the minimum value of the separation distance GAP between the strain adjustment part STR and the edge of the substrate 110 may be 150 um to 180 um.

As described above, according to an embodiment shown in FIGS. 19 and 20, the strain adjustment part STR overlaps not only the corner areas CS1, CS2, CS3, and CS4, but also some portions of the non-display area NDA adjacent to the corner areas CS1, CS2, CS3, and CS4. Accordingly, even when the influence of the bending stress in the double curvature region extends to some portions of the non-display area NDA adjacent to the corner areas CS1, CS2, CS3, and CS4 which are the double curvature regions, the bending stress may be reduced by the strain adjustment part STR, and the occurrence rate of defects due to the bending stress may be reduced.

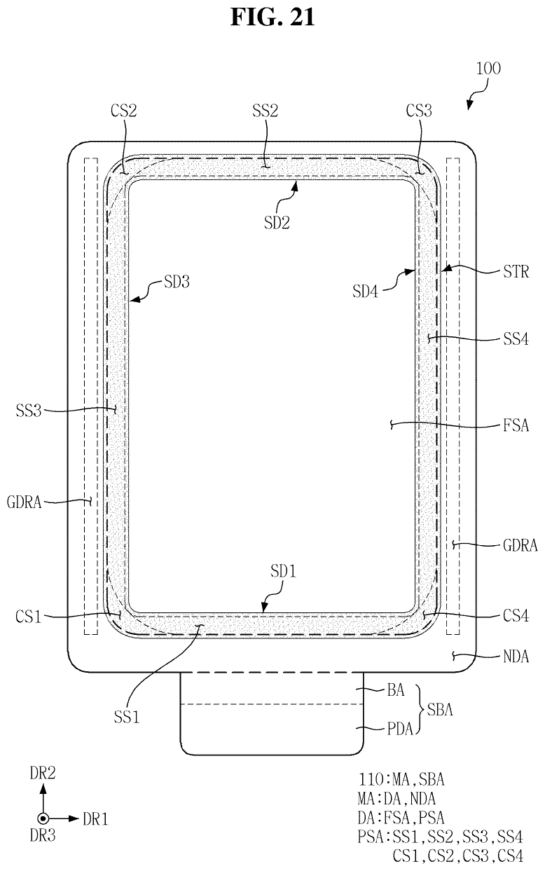

FIGS. 21, 22, 23, and 24 are plan views showing a display panel 100 according to embodiments.

The display panel 100 of the display device 10 according to an embodiment shown in FIG. 21 is substantially the same as that of embodiments shown in FIGS. 11, 12, 13, and 18, except that the strain adjustment part STR further overlaps the side areas SS1, SS2, SS3, and SS4, and therefore redundant description thereof will be omitted below.

Since the peripheral display area PSA is transformed into a shape that is curved toward the bracket 200 (see FIG. 2), the bending stress may be applied.

The strain adjustment part STR may be disposed in a single closed curve shape overlapping the peripheral display area PSA.

Accordingly, when the strain adjustment part STR entirely overlaps the peripheral display area PSA including the corner areas CS1, CS2, CS3, and CS4 and the side areas SS1, SS2, SS3, and SS4, the occurrence rate of defects due to the bending stress may be further reduced.

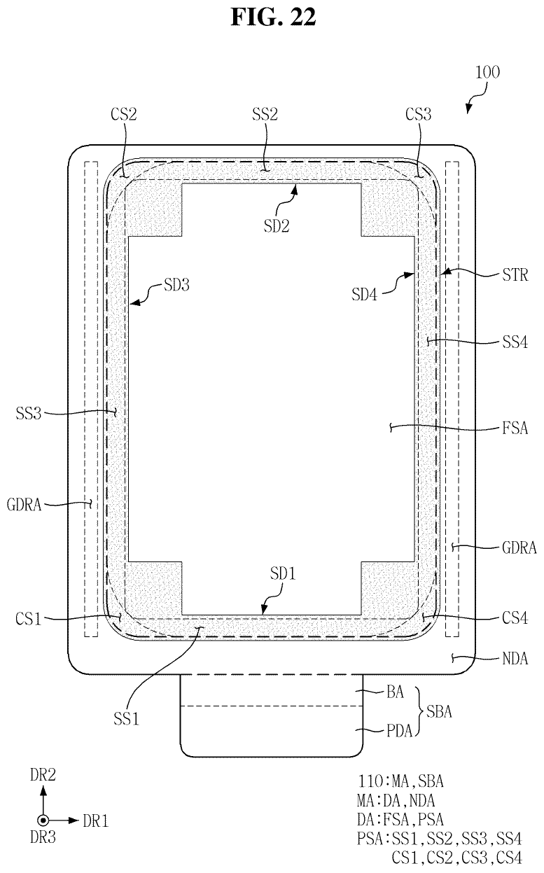

The display panel 100 of the display device 10 according to an embodiment shown in FIG. 22 is substantially the same as that of an embodiment shown in FIG. 21, except that the strain adjustment part STR further overlaps some portions of the front display area FSA adjacent to the corner areas CS1, CS2, CS3, and CS4, and therefore redundant description thereof will be omitted below.

The bending stress in the double curvature region may also be applied to some portions of the front display area FSA adjacent to the corner areas CS1, CS2, CS3, and CS4.

According to an embodiment shown in FIG. 22, the strain adjustment part STR overlaps not only the peripheral display area PSA that is transformed into a bending shape, but also some portions of the front display area FSA adjacent to the corner areas CS1, CS2,

CS3, and CS4. Accordingly, even when the influence of the bending stress in the double curvature region extends to a part of the front display area FSA, the bending stress may be reduced by the strain adjustment part STR, and the occurrence rate of defects due to the bending stress may be reduced.

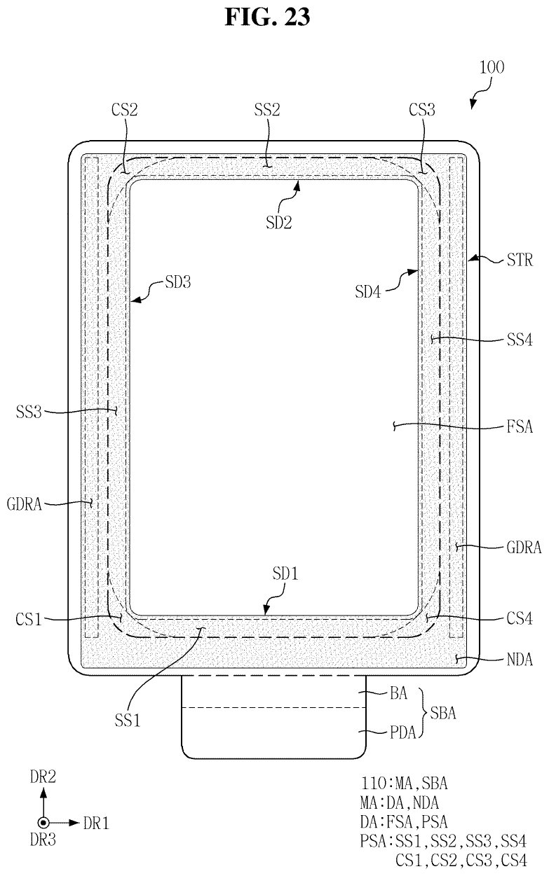

The display panel 100 of the display device 10 according to an embodiment shown in FIG. 23 is substantially the same as that of an embodiment shown in FIG. 21, except that the strain adjustment part STR further overlaps a portion of the non-display area NDA adjacent to the peripheral display area PSA, and therefore redundant description thereof will be omitted below.

According to an embodiment shown in FIG. 23, the strain adjustment part STR overlaps not only the peripheral display area PSA that is transformed into a bending shape, but also a portion of the non-display area NDA adjacent to the peripheral display area PSA.

In this case, the gate driving circuit area GDRA of the non-display area NDA may entirely overlap the strain adjustment part STR.

In this way, even when the bending stress in the peripheral display area PSA extends to the non-display area NDA, the occurrence rate of defects due to the bending stress may be further reduced.

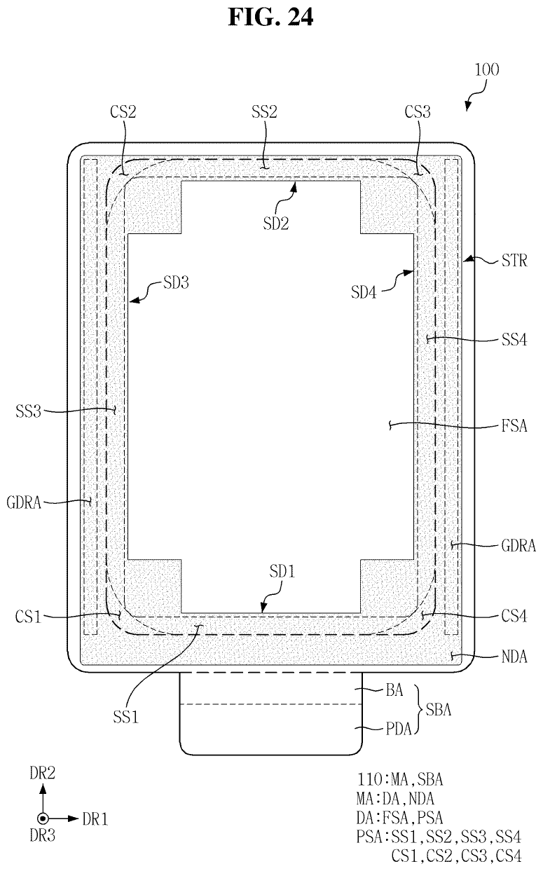

The display panel 100 of the display device 10 shown in FIG. 24 is substantially the same as an embodiment shown in FIG. 23, except that the strain adjustment part STR further overlaps some portions of the front display area FSA adjacent to the corner areas CS1, CS2, CS3, and CS4, and therefore redundant description thereof will be omitted below.

In this way, even when the influence of the bending stress in the double curvature region extends to a part of the front display area FSA, the bending stress may be reduced by the strain adjustment part STR, and the occurrence rate of defects due to the bending stress may be reduced.

However, the effects of the present disclosure are not restricted to the one set forth herein. The above and other effects of the present disclosure will become more apparent to one of daily skill in the art to which the present disclosure pertains by referencing the claims.

What is claimed is:

1. A display device comprising:
a display panel emitting light for image display,
wherein the display panel comprises a substrate, a circuit layer disposed on the substrate, and an element layer disposed on the circuit layer,
a main region of the substrate comprises a display area in which emission areas are arranged, and a non-display area disposed around the display area,
the display area comprises a front display area and a peripheral display area disposed around the front display area and having a curved shape,
the display panel further comprises a strain adjustment part which overlaps corner areas of the peripheral display area adjacent to corners of an edge of the substrate and is spaced apart from the edge of the substrate, the substrate having a first thickness in a portion not overlapping the strain adjustment part, and
a portion of the substrate overlapping the strain adjustment part has a second thickness smaller than the first thickness due to the strain adjustment part.

2. The display device of claim 1, wherein the substrate comprises:
a first support layer;
a barrier layer disposed on the first support layer; and
a second support layer disposed with a third thickness in a portion not overlapping the strain adjustment part on the barrier layer,
wherein the strain adjustment part comprises:
a first groove penetrating at least a part of the first support layer; and
a second groove overlapping the first groove and penetrating a part of the second support layer.

3. The display device of claim 2, wherein an inclination of a side surface of the second groove is greater than or equal to 5° and less than or equal to 15° relative to a plane of the substrate.

4. The display device of claim 2, wherein a thickness of a portion of the second support layer overlapping a bottom surface of the second groove is 50% or more of the third thickness and 85% or less of the third thickness.

5. The display device of claim 4, wherein the thickness of the portion of the second support layer overlapping the bottom surface of the second groove is 3 μm or more.

6. The display device of claim 2, wherein the first support layer has a fourth thickness in a portion not overlapping the strain adjustment part greater than the third thickness, and
a thickness of a portion of the first support layer overlapping the first groove is 10% or less of the fourth thickness.

7. The display device of claim 2, wherein a minimum value of a separation distance between the strain adjustment part and the edge of the substrate is 150 μm to 180 μm.

8. The display device of claim 7, wherein the peripheral display area comprises the corner areas, and side areas parallel to edge sides of the substrate, and
the strain adjustment part further overlaps some portions of the side areas adjacent to the corner areas.

9. The display device of claim 8, wherein the strain adjustment part further overlaps some portions of the non-display area adjacent to the corner areas.

10. The display device of claim 8, wherein the strain adjustment part further overlaps the side areas.

11. The display device of claim 10, wherein the strain adjustment part further overlaps some portions of the front display area adjacent to the corner areas.

12. The display device of claim 10, wherein the strain adjustment part further overlaps a portion of the non-display area adjacent to the peripheral display area.

13. The display device of claim 12, wherein the strain adjustment part further overlaps some portions of the front display area adjacent to the corner areas.

14. The display device of claim 2, wherein the front display area comprises a first side and a second side extending in a first direction and opposite to each other, and a third side and a fourth side extending in a second direction intersecting the first direction and opposite to each other, and
the peripheral display area comprises:
a first side area, a second side area, a third side area, and a fourth side area in contact with the first side, the second side, the third side, and the fourth side of the front display area, respectively;
a first corner area in contact with a vertex where the first side and the third side meet and disposed between the first side area and the third side area;
a second corner area in contact with a vertex where the second side and the third side meet and disposed between the second side area and the third side area;
a third corner area in contact with a vertex where the second side and the fourth side meet and disposed between the second side area and the fourth side area; and
a fourth corner area is in contact with a vertex where the first side and the fourth side meet and disposed between the first side area and the fourth side area,
wherein the strain adjustment part overlaps the first corner area, the second corner area, the third corner area, and the fourth corner area.

15. The display device of claim 2, further comprising:
a bracket supporting the display panel; and
a cover window disposed on the display panel and coupled to the bracket,
wherein the peripheral display area is curved toward the bracket.

16. A display device comprising:
a display panel emitting light for image display;
a bracket supporting the display panel; and
a cover window disposed on the display panel and coupled to the bracket,
wherein the display panel comprises a substrate, a circuit layer disposed on the substrate, and an element layer disposed on the circuit layer,
a main region of the substrate comprises a display area in which emission areas are arranged, and a non-display area disposed around the display area,
the display area comprises a front display area and a peripheral display area disposed around the front display area and having a curved shape toward the bracket,
the display panel further comprises a strain adjustment part which overlaps corner areas of the peripheral display area adjacent to corners of an edge of the substrate and is spaced apart from the edge of the substrate, the substrate having a first thickness in a portion not overlapping the strain adjustment part, and
a portion of the substrate overlapping the strain adjustment part has a second thickness smaller than the first thickness due to the strain adjustment part,
wherein the substrate comprises:
a first support layer;
a barrier layer disposed on the first support layer; and
a second support layer disposed on the barrier layer,
wherein the strain adjustment part comprises:
a first groove penetrating at least a part of the first support layer; and
a second groove overlapping the first groove and penetrating a part of the second support layer.

17. The display device of claim 16, wherein the second support layer is disposed with a third thickness in a portion not overlapping the strain adjustment part,
the first support layer is disposed with a fourth thickness in a portion not overlapping the strain adjustment part greater than the third thickness,
a thickness of a portion of the second support layer overlapping a bottom surface of the second groove is 50% or more of the third thickness and 85% or less of the third thickness, and
a thickness of a portion of the first support layer overlapping the first groove is 10% or less of the fourth thickness.

18. The display device of claim 17, wherein a minimum value of a separation distance between the strain adjustment part and the edge of the substrate is 150 μm to 180 μm.

19. The display device of claim 18, wherein the peripheral display area comprises the corner areas, and side areas parallel to edge sides of the substrate, and
the strain adjustment part further overlaps at least some portions of the side areas adjacent to the corner areas.

20. The display device of claim 19, wherein the strain adjustment part further overlaps at least some portions of the non-display area adjacent to the corner areas.
